(19) United States
(12) Patent Application Publication
(10) Pub. No.: US 2019/0094689 A1
(43) Pub. Date: Mar. 28, 2019

(54) RADIATION-SENSITIVE COMPOSITION AND PATTERN-FORMING METHOD

(71) Applicant: JSR CORPORATION, Tokyo (JP)

(72) Inventor: Motohiro SHIRATANI, TOKYO (JP)

(73) Assignee: JSR CORPORATION, TOKYO (JP)

(21) Appl. No.: 16/197,909

(22) Filed: Nov. 21, 2018

Related U.S. Application Data
(63) Continuation of application No. PCT/JP2017/018746, filed on May 18, 2017.

(51) Int. Cl. G03F 7/004; G03F 7/16; G03F 7/32; G03F 7/20; G03F 7/038; G03F 7/039

(52) U.S. Cl. CPC G03F 7/0044; G03F 7/162; G03F 7/168; G03F 7/322; G03F 7/039; G03F 7/2004; G03F 7/2037; G03F 7/038; G03F 7/325

(57) ABSTRACT

A radiation-sensitive composition includes: particles including a metal oxide as a principal component; an aggregation inhibiting agent for inhibiting aggregation of the particles; and an organic solvent. The aggregation inhibiting agent is preferably a compound having dehydration ability. The compound having dehydration ability is preferably a carboxylic anhydride, an orthocarboxylic acid ester, a carboxylic acid halide or a combination thereof. As the aggregation inhibiting agent, a compound that is capable of coordinating to a metal atom is also preferred. The compound is preferably represented by formula (1). In the formula (1), R¹ represents an organic group having a valency of n; X represents —OH, —COOH, —NCO, —NHR^{a}, —COOR^{A} or —CO—C(R^{L})₂—CO—R^{A}; and n is an integer of 1 to 4. The content of the aggregation inhibiting agent with respect to 100 parts by mass of the particles is preferably no less than 0.001 parts by mass.

R¹X)ₙ (1)

### CROSS-REFERENCE TO RELATED APPLICATIONS

The present application is a continuation application of International Application No. PCT/JP2017/018746, filed May 18, 2017, which claims priority to Japanese Patent Application No. 2016-105607, filed May 26, 2016. The contents of these applications are incorporated herein by reference in their entirety.

### BACKGROUND OF THE INVENTION

### Field of the Invention

The present invention relates to a radiation-sensitive composition and a pattern-forming method.

### Discussion of the Background

Conventionally, in manufacturing processes of semiconductor devices such as IC and LSI, microfabrication by lithography using a radiation-sensitive composition has been carried out. In recent years, integration in integrated circuits has been accompanied by demands for ultrafine pattern formation on a sub-micron scale and a quarter-micron scale. With such demands, shorter exposure wavelengths, e.g., from g-line to i-line, a KrF excimer laser beam, and further an ArF excimer laser beam have come to be employed. In addition, more recently, lithography techniques using extreme ultraviolet rays (EUV), electron beams, and the like in addition to the excimer laser beams have been developed (see Japanese Unexamined Patent Application, Publication No. 2006-171440, Japanese Unexamined Patent Application, Publication No. 2011-16746 and Japanese Unexamined Patent Application, Publication No. 2010-204634).

The lithography techniques carried out through use of EUV or electron beams have been anticipated as next-generation pattern formation techniques that enable a pattern formation on an ultrafine scale of no greater than 32 nm. However, an exposure carried out by using EUV is disadvantageous in low throughput due to insufficient power of an exposure light source, leading to problems which should be solved. In order to solve such problems, devices for improving the output of the light source have been investigated, whereas radiation-sensitive compositions are required to have increased sensitivity. To meet the requirements, use of a metal-containing substance as a component of the radiation-sensitive composition has been investigated. Metal-containing substances generate secondary electrons through absorbing EUV light and the like, and an action of the secondary electrons promotes generation of an acid from an acid generator or the like, whereby improving the sensitivity is believed to be enabled.

However, the metal-containing substances are likely to deteriorate with time, indicating poor stability. Therefore, a radiation-sensitive composition containing a metal-containing substance is disadvantageous in inferior storage stability, i.e., exhibiting impaired sensitivity, as well as impaired lithography performances such as LWR (Line Width Roughness) performance and resolution through the storage for a long period of time.

### SUMMARY OF THE INVENTION

According to an aspect of the present invention, a radiation-sensitive composition includes: particles including a metal oxide as a principal component; an aggregation inhibiting agent for inhibiting aggregation of the particles; and an organic solvent.

According to another aspect of the present invention, a pattern-forming method includes: applying the radiation-sensitive composition directly or indirectly on one face side of a substrate; exposing a film obtained after the applying; and developing the film exposed.

### DESCRIPTION OF EMBODIMENTS

According to an embodiment of the invention, a radiation-sensitive composition includes: particles including a metal oxide as a principal component (hereinafter, may be also referred to as “(A) particles” or “particles (A)”); an aggregation inhibiting agent for inhibiting aggregation of the particles (hereinafter, may be also referred to as “(B) aggregation inhibiting agent” or “aggregation inhibiting agent (B)”); and an organic solvent (hereinafter, may be also referred to as “(C) organic solvent” or “organic solvent (C)”).

According to another embodiment of the invention, a pattern-forming method includes: forming a film; exposing the film; and developing the film exposed, in which the film is formed from the radiation-sensitive composition of the embodiment.

According to the radiation-sensitive composition and the pattern-forming method of the embodiments of the present invention, even when the radiation-sensitive composition is stored for a long period of time, formation of a pattern with high sensitivity, less LWR and high resolution is enabled. Therefore, these can be suitably used for formation of fine resist patterns in lithography processes of various types of electronic devices such as semiconductor devices and liquid crystal devices in which further progress of microfabrication is expected in the future. Hereinafter, embodiments of the present invention will be described in detail. It is to be noted that the present invention is not limited to the following embodiments.

### Radiation-Sensitive Composition

The radiation-sensitive composition of the present embodiment contains the particles (A), the aggregation inhibiting agent (B) and the organic solvent (C). Owing to the components (A) to (C) being contained, the radiation-sensitive composition is superior in storage stability, and is accompanied by less deterioration of LWR performances, resolution and sensitivity with time. Although not necessarily clarified and without wishing to be bound by any theory, the reason for achieving the effects described above due to the radiation-sensitive composition having the aforementioned constitution is inferred as in the following, for example. Specifically, the radiation-sensitive composition contains as the metal-containing substance, particles (A) including the metal oxide as a principal component. Owing to the aggregation inhibiting agent (B) included together with, the particles (A) are less likely to be deteriorated with time by condensation or the like of functional groups on the surfaces of the particles (A) with one another. As a result, the radiation-sensitive composition is believed to be superior in storage stability, and to be accompanied by less deterioration of LWR performances, resolution and sensitivity with time.

Exemplary modes of the radiation-sensitive composition of the present embodiment include: (i) a radiation-sensitive composition containing the particles (A) as the principal component in the total solid content (hereinafter, may be also referred to as “radiation-sensitive composition (I)”); (ii) a radiation-sensitive resin composition further containing a polymer (hereinafter, may be also referred to as “(F) polymer” or “polymer (F)”) having an acid-labile group (hereinafter, may be also referred to as “radiation-sensitive composition (II)”); and the like. The term “total solid content” as referred to herein means the sum of components other than the organic solvent (C) in the radiation-sensitive composition.

The radiation-sensitive composition (I) is capable of forming a pattern through the change in solubility of the particles (A) in the developer solution by an exposure of the film formed. In addition to the components (A) to (C), the radiation-sensitive composition (I) may contain a radiation-sensitive acid generator (hereinafter, may be also referred to as “(D) acid generator” or “acid generator (D)”) and/or an organic acid (hereinafter, may be also referred to as “(G) organic acid” or “organic acid (G)”), as favorable component(s).

The radiation-sensitive composition (II) is capable of forming a pattern through the change in the solubility in the developer solution by the exposure of the film formed, leading to dissociation of the acid-labile group included in the polymer (F). In addition to the components (A) to (C) and (F), the radiation-sensitive composition (II) may contain the acid generator (D) and/or (E) an acid diffusion controller, as favorable component(s).

The radiation-sensitive composition of the present embodiment may contain other optional component(s) within a range not leading to impairment of the effects of the present invention. Each component will be described in the following.

### (A) Particles

The particles (A) include the metal oxide as a principal component. The term “metal oxide” as referred to herein means a compound including a metal atom and an oxygen atom. The term “principal component” as referred to herein means a substance included at the highest percentage content among the substances constituting the particles, preferably no less than 50% by mass, and more preferably no less than 60% by mass. Since the particles (A) include the metal oxide as the principal component, the particles (A) are capable of forming secondary electrons through absorbing a radioactive ray, and an action of the secondary electrons promotes the generation of the acid caused by degradation of the acid generating agent (D) or the like. As a result, the radiation-sensitive composition can have superior sensitivity.

The lower limit of the mean particle diameter of the particles (A) is preferably 0.5 nm, and more preferably 0.8 nm. Meanwhile, the upper limit of the mean particle diameter is preferably 20 nm, more preferably 10 nm, still more preferably 3.0 nm, and particularly preferably 2.5 nm. When the mean particle diameter of the particles (A) falls within the above range, more effective promotion of the generation of the secondary electrons by the particles (A), and in turn more improvements of the sensitivity, the LWR performance and the resolution of the radiation-sensitive composition are enabled. The term “mean particle diameter” as referred to herein means a harmonic mean particle diameter on the basis of scattered light intensity, as measured by DLS (Dynamic Light Scattering) using a light scattering measurement device.

Metal Oxide

The metal atom constituting the metal oxide included in the particles (A) is exemplified by metal atoms from groups 3 to 6, and the like.

Examples of the metal atoms from group 3 include a scandium atom, an yttrium atom, a lanthanum atom, a cerium atom and the like.

Examples of the metal atoms from group 4 include a titanium atom, a zirconium atom, a hafnium atom and the like.

Examples of the metal atoms from group 5 include a vanadium atom, a niobium atom, a tantalum atom and the like.

Examples of the metal atoms from group 6 include a chromium atom, a molybdenum atom, a tungsten atom and the like.

Examples of the metal atoms from group 7 include a manganese atom, a rhenium atom and the like.

Examples of the metal atoms from group 8 include an iron atom, a ruthenium atom, an osmium atom and the like.

Examples of the metal atoms from group 9 include a cobalt atom, a rhodium atom, an iridium atom and the like.

Examples of the metal atoms from group 10 include a nickel atom, a palladium atom, a platinum atom and the like.

Examples of the metal atoms from group 11 include a copper atom, a silver atom, a gold atom and the like.

Examples of the metal atoms from group 12 include a zinc atom, a cadmium atom, a mercury atom and the like.

Examples of the metal atoms from group 13 include an aluminum atom, a gallium atom, an indium atom and the like.

Examples of the metal atoms from group 14 include a germanium atom, a tin atom, a lead atom and the like.

Examples of the metal atoms from group 15 include an antimony atom, a bismuth atom and the like.

Examples of the metal atoms from group 16 include a tellurium atom and the like.

The metal atom constituting the metal oxide is preferably the metal atom from groups 3 to group 14, more preferably the metal atom from group 4, group 5 and group 14, and still more preferably a titanium, a zirconium atom, a tantalum atom, a tungsten atom, a tin atom or a combination thereof.

The metal oxide may contain an additional atom, other than the metal atom and an oxygen atom. Examples of the additional atom include metalloid atoms such as a boron atom and a germanium atom; a carbon atom; a hydrogen atom; a nitrogen atom; a phosphorus atom; a sulfur atom; a halogen atom; and the like. In the case of the metal oxide including the metalloid atom, the percentage content (% by mass) of the metalloid atom in the metal oxide is typically less than the percentage content of the metal atom.

The lower limit of a total percentage content of the metal atom and the oxygen atom in the metal oxide is preferably 30% by mass, more preferably 50% by mass, still more preferably 70% by mass, and particularly preferably 90% by mass. Meanwhile, the upper limit of the total percentage content is preferably 99.9% by mass. When the total percentage content of the metal atom and the oxygen atom falls within the above range, a more effective promotion of the generation of the secondary electrons by the particles (A), and in turn a more improvement of the sensitivity of the radiation-sensitive composition of the present embodiment are enabled. It is to be noted that the total percentage content of the metal atom and the oxygen atom may be 100% by mass.

A component other than the metal atoms constituting the metal oxide is preferably an organic acid (hereinafter, may be also referred to as “organic acid (a)”). The “organic acid” as referred to herein means an acidic organic compound, and the “organic compound” as referred to means a compound having at least one carbon atom.

When the particles (A) contain the metal oxide constituted from the metal atom and the organic acid (a), more improvements of the sensitivity, the LWR performance and the resolution of the radiation-sensitive composition of the present embodiment are achieved. The improvements are considered to result from, for example, the organic acid (a) being present in the vicinity of surfaces of the particles (A) due to an interaction with the metal atom is believed to improve dispersibility of the particles (A) in the solvent.

The lower limit of pKa of the organic acid (a) is preferably 0, more preferably 1, still more preferably 1.5, and particularly preferably 3. Meanwhile, the upper limit of the pKa is preferably 7, more preferably 6, still more preferably 5.5, and particularly preferably 5. When the pKa of the organic acid (a) falls within the above range, it is possible to adjust the interaction with the metal atom to be moderately weak, whereby more improvements of the sensitivity, the LWR performance and the resolution of the radiation-sensitive composition are enabled. As used herein, in the case of the organic acid (a) being a polyvalent acid, the pKa of the organic acid (a) as referred to means a primary acid dissociation constant, i.e., a logarithmic value of a dissociation constant for dissociation of the first proton.

The organic acid (a) may be either a low molecular weight compound or a high molecular weight compound, and a low molecular weight compound is preferred in light of adjusting the interaction with the metal atom to be more appropriately weak. The “low molecular weight compound” as referred to means a compound having a molecular weight of no greater than 1,500, whereby the “high molecular weight compound” as referred to means a compound having a molecular weight of greater than 1,500. The lower limit of the molecular weight of the organic acid (a) is preferably 50, and more preferably 80. Meanwhile, the upper limit of the molecular weight is preferably 1,000, more preferably 500, further more preferably 400, and particularly preferably 300. When the molecular weight of the organic acid (a) falls within the above range, it is possible to adjust the dispersibility of the particles (A) to be more appropriate, and consequently more improvements of the sensitivity, the LWR performance and the resolution of the radiation-sensitive composition of the present embodiment are enabled.

The organic acid (a) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid and shikimic acid;

dicarboxylic acids such as oxalic acid, malonic acid, maleic acid, methylmalonic acid, fumaric acid, adipic acid, sebacic acid, phthalic acid and tartaric acid;

carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphonic acid include methylphosphonic acid, ethylphosphonic acid, t-butylphosphonic acid, cyclohexylphosphonic acid, phenylphosphonic acid, and the like.

Examples of the phenol include: monovalent phenols such as phenol, cresol, 2,6-xylenol and naphthol;

divalent phenols such as catechol, resorcinol, hydroquinone and 1,2-naphthalenediol;

phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the acid imide include:

carboxylic imides such as maleimide and succinimide;

sulfonic imides such as a di(trifluoromethanesulfonic acid) imide and di(pentafluoroethanesulfonic acid) imide; and the like.

Examples of the oxime include:

aldoximes such as benzaldoxime and salicylaldoxime;

ketoximes such as diethylketoxime, methylethylketoxime and cyclohexanoneoxime; and the like.

Examples of the sulfonamide include methyl sulfonamide, ethylsulfonamide, benzenesulfonamide, toluenesulfonamide, and the like.

In light of more improving the sensitivity, the LWR performance and the resolution of the radiation-sensitive composition, as the organic acid (a), the carboxylic acid is preferred; the monocarboxylic acid is more preferred; and methacrylic acid and benzoic acid are still more preferred.

The metal oxide is preferably a metal oxide constituted from the metal atom and the organic acid (a), more preferably a metal oxide constituted from the organic acid (a) and a metal atom from group 4, group 5 and group 14, and still more preferably a metal oxide constituted from: a titanium atom, a zirconium atom, a hafnium atom, a tantalum atom, a tungsten atom or a tin atom; and methacrylic acid or benzoic acid.

The lower limit of a percentage content of the metal oxide in the particles (A) is preferably 60% by mass, more preferably 80% by mass, and still more preferably 95% by mass. It is to be noted that the percentage content of the metal oxide may be 100% by mass. When the percentage content of the metal oxide falls within the above range, more improvements of the sensitivity, the LWR performance and the resolution of the radiation-sensitive composition are enabled. The particles (A) may include either only one type, or two or more types of the metal oxide.

In the case in which the particles (A) contain as the principal component, the metal oxide, which is constituted from the metal atom and the organic acid, the lower limit of a percentage content of the organic acid (a) in the particles (A) is preferably 1% by mass, more preferably 5% by mass, and still more preferably 10% by mass. Meanwhile, the upper limit of the percentage content is preferably 90% by mass, more preferably 70% by mass, and still more preferably 50% by mass. When the percentage content of the organic acid (a) falls within the above range, it is possible to adjust the dispersibility of the particles (A) to be further appropriate, and consequently more improvements of the sensitivity, the LWR performance and the resolution of the radiation-sensitive composition of the present embodiment are enabled. The particles (A) may include either only one type, or two or more types of the organic acid (a).

In the case in which the radiation-sensitive composition is the radiation-sensitive composition (I), the lower limit of the content of the particles (A) with respect to the total solid content is preferably 50% by mass, more preferably 70% by mass, and still more preferably 90% by mass. The upper limit of the content is preferably 99% by mass, and more preferably 95% by mass.

In the case in which the radiation-sensitive composition is the radiation-sensitive composition (II), the lower limit of the content of the particles (A) with respect to the total solid content is preferably 1% by mass, more preferably 2% by mass, and still more preferably 3% by mass. The upper limit of the content is preferably 40% by mass, more preferably 20% by mass, and still more preferably 10% by mass. The lower limit of the content of the particles (A) in the radiation-sensitive composition (II), with respect to 100 parts by mass of the polymer (F) is preferably 1 part by mass, more preferably 2 parts by mass, and still more preferably 3 parts by mass. The upper limit of the content is preferably 40 parts by mass, more preferably 20 parts by mass, and still more preferably 10 parts by mass.

When the content of the particles (A) falls within the above range, more improvements of the sensitivity, the LWR performance and the resolution of the radiation-sensitive composition of the present embodiment are enabled. The radiation-sensitive composition may include either only one type, or two or more types of the particles (A).

### Synthesis Procedure of (A) Particles

The particles (A) may be synthesized by, for example, a procedure of carrying out a hydrolytic condensation reaction by using (b) a metal-containing compound, a procedure of carrying out a ligand substitution reaction by using the metal-containing compound (b), or the like. The “hydrolytic condensation reaction” as referred to means a reaction in which a hydrolyzable group comprised in the metal-containing compound (b) is hydrolyzed to give —OH, and two —OHs thus obtained undergo dehydrative condensation to form —O—.

(b) Metal-Containing Compound

The metal-containing compound (b) is: a metal compound (I) having a hydrolyzable group; a hydrolysis product of the metal compound (I) having a hydrolyzable group; a hydrolytic condensation product of the metal compound (I) having a hydrolyzable group; or a combination thereof. The metal compound (I) may be used either alone of one type, or in combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxy group, a butoxy group, and the like.

Examples of the acyloxy group include an acetoxy group, an ethylyloxy group, a propionyloxy group, a butyryloxy group, a t-butyryloxy group, a t-amylyloxy group, a n-hexanecarbonyloxy group, a n-octanecarbonyloxy group, and the like.

As the hydrolyzable group, an alkoxy group and an acyloxy group are preferred, and an isopropoxy group and an acetoxy group are more preferred.

In a case in which the metal-containing compound (b) is a hydrolytic condensation product of the metal compound (I), the hydrolytic condensation product of the metal compound (I) may be a hydrolytic condensation product of the metal (I) having a hydrolyzable group with a compound including a metalloid atom, within a range not leading to impairment of the effects of the embodiments of the present invention. In other words, the hydrolytic condensation product of the metal compound (I) may also include a metalloid atom within a range not leading to impairment of the effects of the embodiments of the present invention. The metalloid atom is exemplified by a boron atom, a germanium atom, an antimony atom, a tellurium atom and the like. The percentage content of the metalloid atom in the hydrolytic condensation product of the metal compound (I) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (I) is exemplified by compounds represented by the following formula (1) (hereinafter, may be also referred to as a “metal compound (I-1)”), and the like. By using the metal compound (I-1), forming a stable metal oxide is enabled, whereby more improvements of the sensitivity, the LWR performance and the resolution of the radiation-sensitive composition are enabled.

LₐMY_{b} (A)

In the above formula (A), M represents a metal atom; L represents a ligand; a is an integer of 0 to 2, wherein in a case where a is 2, a plurality of Ls may be identical or different; Y represents a hydrolyzable group selected from a halogen atom, an alkoxy group and an acyloxy group; b is an integer of 2 to 6; and a plurality of Ys may be identical or different. It is to be noted that L is a ligand that does not fall under the definition of Y.

The metal atom represented by M is exemplified by metal atoms similar to those exemplified in connection with the metal atoms which may constitute the metal oxide included in the particles (A), and the like.

The ligand represented by L is exemplified by a monodentate ligand and a polydentate ligand.

Exemplary monodentate ligand includes a hydroxo ligand, a carboxy ligand, an amido ligand, ammonia, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Exemplary polydentate ligand includes a hydroxy acid ester, a ρ-diketone, a β-keto ester, a β-dicarboxylic acid ester, a hydrocarbon having a π bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples of the halogen atom which may be represented by Y include a fluorine atom, a chlorine atom, a bromine atom, an iodine atom, and the like.

Examples of the alkoxy group which may be represented by Y include a methoxy group, an ethoxy group, a propoxy group, a butoxy group, and the like.

Examples of the acyloxy group which may be represented by Y include an acetoxy group, an ethylyloxy group, a butyryloxy group, a t-butyryloxy group, a t-amylyloxy group, a n-hexanecarbonyloxy group, a n-octanecarbonyloxy group, and the like.

Y represents preferably an alkoxy group or an acyloxy group, and more preferably an isopropoxy group or an acetoxy group.

Preferably, b is 3 or 4, and more preferably 4. When b is the above specified value, it is possible to increase the percentage content of the metal oxide in the particles (A), whereby more effective promotion of the generation of the secondary electrons by the particles (A) is enabled. Consequently, a more improvement of the sensitivity of the radiation-sensitive composition is enabled.

As the metal-containing compound (b), a metal alkoxide that is neither hydrolyzed nor hydrolytic condensed, and a metal acyloxide that is neither hydrolyzed nor hydrolytically condensed are preferred.

Examples of the metal-containing compound (b) include zirconium tetra-n-butoxide, zirconium tetra-n-propoxide, zirconium tetraisopropoxide, hafnium tetraethoxide, indium triisopropoxide, hafnium tetraisopropoxide, hafnium tetrabutoxide, tantalum pentaethoxide, tantalum pentabutoxide, tungsten pentamethoxide, tungsten pentabutoxide, tungsten hexaethoxide, tungsten hexabutoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxidestearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomers, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyano propyltrimethoxyzirconium, 3-isocyanopropyltriethoxyzirconium, triethoxymono(acetylacetonato)titanium, tri-n-propoxymono(acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetrabutoxide, lanthanum oxide, yttrium oxide, and the like. Of these, metal alkoxides and metal acyloxides are preferred, metal alkoxides are more preferred, and alkoxides of titanium, zirconium, hafnium, tantalum, tungsten and tin are still more preferred.

In the case of using the organic acid in synthesizing the particles (A), the lower limit of the amount of the organic acid used is preferably 10 parts by mass, and more preferably 30 parts by mass with respect to 100 parts by mass of the metal-containing compound (b). Meanwhile, the upper limit of the amount of the organic acid used is preferably 1,000 parts by mass, more preferably 700 parts by mass, still more preferably 200 parts by mass, and particularly preferably 100 parts by mass with respect to 100 parts by mass of the metal-containing compound (b). When the amount of the organic acid used falls within the above range, an appropriate adjustment of a percentage content of the organic acid (a) in the particles (A) to be obtained is enabled, and consequently more improvements of the sensitivity, the LWR performance and the resolution of the radiation-sensitive composition are enabled.

Upon the synthesis reaction of the particles (A), in addition to the metal compound (I) and the organic acid (a), a compound that may be the polydentate ligand represented by L in the compound of the formula (A), a compound that may be a bridging ligand, etc., may also be added. The compound that may be the bridging ligand is exemplified by a compound having a hydroxy group, an isocyanate group, an amino group, an ester group and an amide group each in a plurality of number, and the like.

A procedure for carrying out the hydrolytic condensation reaction using the metal-containing compound (b) may be exemplified by: a procedure of hydrolytically condensing the metal-containing compound (b) in a solvent containing water; and the like. In this case, other compound having a hydrolyzable group may be added as needed. The lower limit of the amount of water used for the hydrolytic condensation reaction is preferably 0.2 times molar amount, more preferably an equimolar amount, and still more preferably 3 times molar amount with respect to the hydrolyzable group included in the metal-containing compound (b) and the like. The upper limit of the amount of water is preferably 20 times molar amount, more preferably 15 times molar amount, and further more preferably 10 times molar amount. When the amount of the water in the hydrolytic condensation reaction falls within the above range, it is possible to increase the percentage content of the metal oxide in the particles (A) to be obtained, whereby more improvements of the sensitivity, the LWR performance and the resolution of the radiation-sensitive composition are enabled.

A procedure for carrying out the ligand substitution reaction using the metal-containing compound (b) may be exemplified by: a procedure of mixing the metal-containing compound (b) and the organic acid (a); and the like. In this case, the mixing may be carried out either in a solvent or without a solvent. Upon the mixing, a base such as triethylamine may be added as needed. An amount of the base added is, for example, no less than 1 part by mass and no greater than 200 parts by mass with respect to a total amount of the metal-containing compound (b) and the organic acid (a) used being 100 parts by mass.

The solvent for use in the synthesis reaction of the particles (A) is not particularly limited, and solvents similar to those exemplified in connection with the solvent (C) described later may be used. Of these, alcohol solvents, ether solvents, ester solvents, and hydrocarbon solvents are preferred; alcohol solvents, ether solvents and ester solvents are more preferred; polyhydric alcohol partial ether solvents, monocarboxylic acid ester solvents and cyclic ether solvents are still more preferred; and propylene glycol monoethyl ether, ethyl acetate and tetrahydrofuran are particularly preferred.

In the case of using the organic solvent in the synthesis reaction of the particles (A), the organic solvent used may be either removed after the completion of the reaction, or directly used as the organic solvent (C) in the radiation-sensitive composition without removal thereof.

The lower limit of the temperature of the synthesis reaction of the particles (A) is preferably 0° C., and more preferably 10° C. The upper limit of the aforementioned temperature is preferably 150° C., and more preferably 100° C.

The lower limit of the time period of the synthesis reaction of the particles (A) is preferably 1 min, more preferably 10 min, and still more preferably 1 hour. The upper limit of the time period is preferably 100 hrs, more preferably 50 hrs, and further more preferably 10 hrs.

### (B) Aggregation Inhibiting Agent

The aggregation inhibiting agent (B) inhibits aggregation of the particles (A). The term “aggregation” as referred to herein means gathering of a plurality of particles (A) together to form a larger particle.

Any substance having the aforementioned property may be used as the aggregation inhibiting agent (B) without particular limitations, which is exemplified by a compound having dehydration ability (hereinafter, may be also referred to as “dehydrating agent (B1)”), a compound that is capable of coordinating to a metal atom (hereinafter, may be also referred to as “ligand compound (B2)”), and the like.

The radiation-sensitive composition containing the dehydrating agent (B1) has a lowered concentration of water therein. Thus, aggregation of the particles (A) which is assumed to result from hydrolytic condensation of hydrolyzable groups on the surfaces of the particles (A) with each other is inhibited. Furthermore, when the radiation-sensitive composition contains the ligand compound (B2), elimination of the compound coordinated to the metal atoms on the surfaces of the particle (A) is inhibited. Thus, aggregation of the particles (A) which is assumed to result from coordination sites uncoordinated to the metal atoms on the surfaces of the particle (A) is inhibited.

### (B1) Dehydrating Agent

The dehydrating agent (B1) means a substance that is capable of removing water in the radiation-sensitive composition. As the dehydrating agent (B1), either an organic compound or an inorganic compound may be used as long as it has the aforementioned property. Of these, in light of possible decrease in effects on the radiation-sensitive composition by a substance generated from the reaction with water, the organic compound is preferred. Examples of the dehydrating agent (B1) being the inorganic compound include anhydrous calcium sulfate, anhydrous magnesium sulfate, zeolite, and the like.

The dehydrating agent (B1) being the organic compound is exemplified by a carboxylic anhydride, an orthocarboxylic acid ester, a carboxylic acid halide, and the like.

The carboxylic anhydride is exemplified by compounds represented by the following formula (a). The orthocarboxylic acid ester is exemplified by compounds represented by the following formula (b).

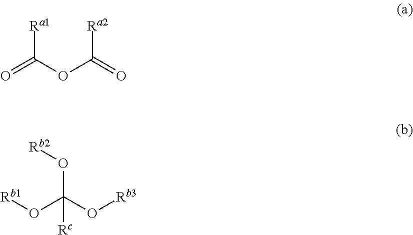

In the above formula (a), R^{a1} and R^{a2} each independently represent a hydrogen atom or a substituted or unsubstituted monovalent hydrocarbon group having 1 to 20 carbon atoms, or the groups R^{a1} and R^{a2} taken together represent a ring structure having 4 to 20 ring atoms together with the atom chain to which R^{a1} and R^{a2} bond.

In the above formula (b), R^{b1}, R^{b2} and R^{b3} each independently represent a substituted or unsubstituted monovalent hydrocarbon group having 1 to 20 carbon atoms; R^{c} represents a hydrogen atom or a substituted or unsubstituted monovalent hydrocarbon group having 1 to 20 carbon atoms; at least two of R^{b1}, R^{b2}, R^{b3} and R^{c} may taken together represent a ring structure having 4 to 20 ring atoms together with the atom chain to which the at least two of R^{b1}, R^{b2}, R^{b3} and R^{c} bond.

The “hydrocarbon group” involves a chain hydrocarbon group, an alicyclic hydrocarbon group and an aromatic hydrocarbon group. The “hydrocarbon group” may be either a saturated hydrocarbon group or an unsaturated hydrocarbon group. The “chain hydrocarbon group” as referred to herein means a hydrocarbon group not having a ring structure but being constituted only from a chain structure, and involves both a linear hydrocarbon group and a branched hydrocarbon group. The “alicyclic hydrocarbon group” as referred to herein means a hydrocarbon group having as a ring structure, not an aromatic ring structure but only an alicyclic structure, and involves both a monocyclic alicyclic hydrocarbon group and a polycyclic alicyclic hydrocarbon group. It is not necessary that the alicyclic hydrocarbon group is constituted from only the alicyclic structure, and a part thereof may also include a chain structure. The “aromatic hydrocarbon group” as referred to herein means a hydrocarbon group that includes an aromatic ring structure as the ring structure. It is not necessary that the aromatic hydrocarbon group is constituted from only the aromatic ring structure, and a part thereof may also include a chain structure and/or an alicyclic structure.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a n-propyl group and an i-propyl group;

alkenyl groups such as an ethenyl group, a propenyl group and a butenyl group;

alkynyl groups such as an ethynyl group, a propynyl group and a butynyl group; and the like. Of these, the alkyl groups are preferred, the alkyl groups having 1 to 4 carbon atoms are more preferred, a methyl group, an ethyl group and an i-propyl group are still more preferred, and an ethyl group is particularly preferred.

Examples of the monovalent alicyclic hydrocarbon group having 3 to 20 carbon atoms include:

monocyclic monovalent alicyclic saturated hydrocarbon groups such as a cyclopentyl group and a cyclohexyl group;

monocyclic monovalent alicyclic unsaturated hydrocarbon groups such as a cyclopentenyl group and a cyclohexenyl group;

polycyclic monovalent alicyclic saturated hydrocarbon groups such as a norbornyl group, an adamantyl group, a tricyclodecyl group and a tetracyclododecyl group;

polycyclic monovalent alicyclic unsaturated hydrocarbon groups such as a norbornenyl group, a tricyclodecenyl group and a tetracyclododecenyl group; and the like. Of these, monocyclic monovalent alicyclic saturated hydrocarbon groups and polycyclic monovalent alicyclic saturated hydrocarbon groups are preferred, and a cyclopentyl group, a cyclohexyl group, a norbornyl group and an adamantyl group are more preferred.

Examples of the monovalent aromatic hydrocarbon group having 6 to 20 carbon atoms include:

aryl groups such as a phenyl group, a tolyl group, a xylyl group, a mesityl group, a naphthyl group, a methylnaphthyl group, an anthryl group and a methylanthryl group;

aralkyl groups such as a benzyl group, a phenethyl group, a naphthylmethyl group and an anthrylmethyl group; and the like.

Examples of a substituent for the hydrocarbon group include a hydroxy group, a cyano group, a nitro group, an acyl group, a monovalent oxyhydrocarbon group, a monovalent carbonyloxyhydrocarbon group, a halogen atom, and the like.

R^{a1} and R^{a2} in the above formula (a) each represent preferably a hydrocarbon group, more preferably a chain hydrocarbon group, still more preferably an alkyl group or an alkenyl group, particularly preferably an alkenyl group, and further particularly preferably an isopropenyl group.

R^{b1}, R^{b2} and R^{b3} in the above formula (b) each represent preferably a hydrocarbon group, more preferably a chain hydrocarbon group, still more preferably an alkyl group or an alkenyl group, particularly preferably an alkyl group, and further particularly preferably a methyl group or an ethyl group. R^{c} represents preferably a hydrogen atom.

Examples of the ring structure having 4 to 20 ring atoms taken together represented by the groups R^{a1} and R^{a2} in the above formula (a) together with the atom chain to which R^{a1} and R^{a2} bond include oxacycloalkane structures such as an oxacyclopentane structure, an oxacyclohexane structure, an oxacycloheptane structure and an oxacyclooctane structure, and the like.

Examples of the ring structure having 4 to 20 ring atoms taken together represented by at least two of R^{b1}, R^{b2}, R^{b3} and R^{c} in the above formula (b) together with the atom chain to which the at least two of R^{b1}, R^{b2}, R^{b3} and R^{c} bond include dioxacycloalkane structures such as a dioxacyclopentane structure, a dioxacyclohexane structure, a dioxacycloheptane structure and a dioxacyclooctane structure, and the like.

Examples of the carboxylic anhydride include:

saturated aliphatic monocarboxylic anhydrides such as formic anhydride, acetic anhydride, propionic anhydride, butyric anhydride, valeric anhydride and caproic anhydride;

unsaturated aliphatic monocarboxylic anhydrides such as (meth)acrylic anhydrides, propiolic anhydride and crotonic anhydride;

saturated aliphatic dicarboxylic anhydrides such as oxalic anhydride, malonic anhydride, succinic anhydride and glutaric anhydride (including intramolecular anhydrides);

ring-containing carboxylic anhydrides such as benzoic anhydride, toluic anhydride and furancarboxylic anhydride; and the like. Of these, saturated aliphatic monocarboxylic anhydrides and unsaturated aliphatic monocarboxylic anhydrides are preferred, and acetic anhydride and (meth)acrylic anhydrides are more preferred.

Examples of the orthocarboxylic acid ester include orthoformic acid esters, orthoacetic acid esters, orthopropionic acid esters, orthobenzoic acid esters, and the like. Of these, orthoformic acid esters are preferred, and triethyl orthoformate is more preferred.

Examples of the carboxylic acid halide include:

saturated aliphatic monocarboxylic acid halides such as formic acid halide, acetic acid halide, propionic acid halide, butyric acid halide, valeric acid halide and caproic acid halide;

unsaturated aliphatic monocarboxylic acid halides such as (meth)acrylic acid halide, propiolic acid halide and crotonic acid halide;

saturated aliphatic dicarboxylic acid dihalides such as oxalic acid dihalide, malonic acid dihalide, succinic acid dihalide and glutaric acid dihalide;

ring-containing carboxylic acid halides such as benzoic acid halide, toluic acid halide and furancarboxylic acid halide; and the like. Of these, saturated aliphatic monocarboxylic acid halides, unsaturated aliphatic monocarboxylic acid halides and ring-containing carboxylic acid halides are preferred, unsaturated aliphatic monocarboxylic acid halides and ring-containing carboxylic acid halides are more preferred, (meth)acrylic acid halides and benzoic acid halide are still more preferred, and (meth)acrylic acid chloride and benzoic acid chloride are particularly preferred.

### (B2) Ligand Compound

The ligand compound (B2) is a compound that is capable of coordinating to a metal atom. As the ligand compound (B2), any compound having the aforementioned property may be used, and the compound is exemplified by compounds having a functional group that is capable of coordinating to a metal atom, and the like. Exemplary functional groups that are capable of coordinating to a metal atom include a hydroxy group, a carboxy group, an isocyanate group, an amino group, a carbonyloxy hydrocarbon group, a carbonylalkanediylcarbonyl hydrocarbon group, and the like.

Examples of the ligand compound (B2) include compounds represented by the following formula (1), and the like.

R¹X)ₙ (1)

In the above formula (1), R¹ represents an organic group having a valency of n; X represents —OH, —COOH, —NCO, —NHR^{a}, —COOR^{A} or —CO—C(R^{L})₂—CO—R^{A}, wherein R^{a} represents a hydrogen atom or a monovalent organic group, R^{A} represents a monovalent organic group, and R^{L}s each independently represent a hydrogen atom or a monovalent organic group; and n is an integer of 1 to 4, wherein, in a case where n is 2 or greater, a plurality of Xs may be identical or different.

The organic group having a valency of n represented by R¹ is exemplified by a hydrocarbon group having a valency of n, a hetero atom-containing group having a valency of n and including a group having a hetero atom between two adjacent carbon atoms of the hydrocarbon group having a valency of n, a group having a valency of n derived from the hydrocarbon group or the hetero atom-containing group each having a valency of n by substituting a part or all of hydrogen atoms with a substituent, and the like.

Examples of the hydrocarbon group having a valency of n include: chain hydrocarbons having 1 to 30 carbon atoms, e.g., alkanes such as methane, ethane, propane and butane, alkenes such as ethene, propene, butene and pentene, alkynes such as ethyne, propyne, butyne and pentyne, and the like;

alicyclic hydrocarbon having 3 to 30 carbon atoms, e.g., cycloalkanes such as cyclopropane, cyclobutane, cyclopentane, cyclohexane, norbornane and adamantane, cycloalkenes such as cyclopropene, cyclobutene, cyclopentene, cyclohexene and norbornene, and the like;

groups obtained by removing n hydrogen atom(s) from a hydrocarbon such as an aromatic hydrocarbon having 6 to 30 carbon atoms, e.g., arenes such as benzene, toluene, xylene, mesitylene, naphthalene, methylnaphthalene, dimethylnaphthalene and anthracene, and the like.

The group having a hetero atom is exemplified by a group having at least one selected from the group consisting of an oxygen atom, a nitrogen atom, a silicon atom, a phosphorus atom and a sulfur atom, and the like. Examples of the group having a hetero atom include —O—, —NH—, —CO—, —S—, a group obtained by combining the same, and the like. Of these, —O— is preferred.

Examples of the substituent include:

halogen atoms such as a fluorine atom, a chlorine atom, a bromine atom and an iodine atom;

alkoxy groups such as a methoxy group, an ethoxy group and a propoxy group;

alkoxycarbonyl groups such as a methoxycarbonyl group and an ethoxycarbonyl group;

alkoxycarbonyloxy groups such as a methoxycarbonyloxy group and an ethoxycarbonyloxy group;

acyl groups such as a formyl group, an acetyl group, a propionyl group, a butyryl group and a benzoyl group;

a cyano group; a nitro group; and the like.

The monovalent organic group which may be represented by R^{a} in —NHR^{a} is exemplified by a monovalent hydrocarbon group having 1 to 20 carbon atoms, a hetero atom-containing group that includes a group having a hetero atom between two adjacent carbon atoms of the monovalent hydrocarbon group, a group obtained by substituting with a substituent a part or all of hydrogen atoms included in the monovalent hydrocarbon group or the hetero atom-containing group, and the like. R^{a} represents preferably the monovalent hydrocarbon group, more preferably the monovalent chain hydrocarbon group, still more preferably an alkyl group, and particularly preferably a methyl group.

The monovalent organic group represented by R^{A} in —COOR^{A} or —CO—C(R^{L})₂—CO—R^{A} is exemplified by monovalent organic groups similar to those exemplified in connection with R^{a}.

The monovalent organic group which may be represented by R^{L} in —CO—C(R^{L})₂—CO—R^{A} is exemplified by monovalent organic groups similar to those exemplified in connection with R^{a}. Here, two R^{L}s may be identical or different.

When n is 1, R¹ represents preferably a monovalent chain hydrocarbon group, a monovalent aromatic hydrocarbon group or a monovalent hetero atom-containing group, more preferably an alkyl group or an alkenyl group, and still more preferably a propyl group or a 2-propenyl group.

When n is 2, R¹ represents preferably a divalent chain hydrocarbon group, a divalent aromatic hydrocarbon group or a divalent hetero atom-containing group, more preferably an alkanediyl group, an alkenediyl group, an arenediyl group or an alkanediyloxyalkanediyl group, and still more preferably a 1,2-ethanediyl group, a 1,2-propanediyl group, a butanediyl group, a hexanediyl group, an ethenediyl group, a xylene diyl group or an ethanediyloxyethanediyl group.

When n is 3, R¹ represents preferably a trivalent chain hydrocarbon group, more preferably an alkanetriyl group, and still more preferably a 1,2,3-propanetriyl group.

When n is 4, R¹ represents preferably a tetravalent chain hydrocarbon group, more preferably an alkanetetrayl group, and still more preferably a 1,2,3,4-butanetetrayl group.

The compound represented by the above formula (1) is exemplified by compounds represented by the following formulae (L-1-1) to (L-1-6) (hereinafter, may be also referred to as “compounds (L-1-1) to (L-1-6)”), and the like.

R¹OH)ₙ (L-1-1)

R¹COOH)ₙ (L-1-2)

R¹NCO)ₙ (L-1-3)

R¹NHR^{a})ₙ (L-1-4)

R¹COOR^{A})ₙ (L-1-5)

R¹COC(R^{L})₂COR^{A})ₙ (L-1-6)

In the above formulae (L-1-1) to (L-1-6), R¹, R^{a}, R^{A}, R^{L} and n are as defined in the above formula (1).

In the compound (L-1-1), n is preferably 2 to 4.

When n is 2, examples of the compound (L-1-1) include:

alkylene glycols such as ethylene glycol, propylene glycol, butylene glycol and hexamethylene glycol;

dialkylene glycols such as diethylene glycol, dipropylene glycol, dibutylene glycol, triethylene glycol and tripropylene glycol;

cycloalkylene glycols such as cyclohexanediol, cyclohexanedimethanol, norbornanediol, norbornanedimethanol and adamantanediol;

aromatic ring-containing glycols such as 1,4-benzenedimethanol and 2,6-naphthalenedimethanol;

dihydric phenols such as catechol, resorcinol and hydroquinone; and the like.

When n is 3, examples of the compound (L-1-1) include:

alkanetriols such as glycerin and 1,2,4-butanetriol;

cycloalkanetriols such as 1,2,4-cyclohexanetriol and 1,2,4-cyclohexanetrimethanol;

aromatic ring-containing glycols such as 1,2,4-benzenetrimethanol and 2,3,6-naphthalenetrimethanol;

trihydric phenols such as pyrogallol and 2,3,6-naphthalenetriol;

trimethylolpropaneethoxylate; and the like.

When n is 4, examples of the compound (L-1-1) include:

alkanetetraols such as erythritol and pentaerythritol;

cycloalkanetetraols such as 1,2,4,5-cyclohexanetetraol;

aromatic ring-containing tetraols such as 1,2,4,5-benzenetetramethanol;

tetrahydric phenols such as 1,2,4,5-benzenetetraol; and the like.

Of these, the compounds (L-1-1) in which n is 2 or 3 are preferred, alkylene glycol, dialkylene glycol, alkanetriol and trimethylolpropaneethoxylate are more preferred, and propylene glycol, diethylene glycol, glycerin and trimethylolpropaneethoxylate are still more preferred.

When n is 1, examples of the compound (L-1-2) include:

chain saturated monocarboxylic acids such as acetic acid and propionic acid;

unsaturated monocarboxylic acids such as acrylic acid, methacrylic acid and trans-2,3-dimethylacrylic acid;

alicyclic monocarboxylic acids such as cyclohexanedicarboxylic acid, norbornanecarboxylic acid and adamantanecarboxylic acid;

aromatic monocarboxylic acids such as benzoic acid and naphthalenecarboxylic acid; and the like.

When n is 2, examples of the compound (L-1-2) include:

chain saturated dicarboxylic acids such as oxalic acid, malonic acid, succinic acid, glutaric acid and adipic acid;

chain unsaturated dicarboxylic acids such as maleic acid, fumaric acid and trans-2,3-dimethylacrylic acid;

alicyclic dicarboxylic acids such as 1,4-cyclohexanedicarboxylic acid, norbornanedicarboxylic acid and adamantanedicarboxylic acid;

aromatic dicarboxylic acids such as phthalic acid, terephthalic acid, 2,6-naphthalenedicarboxylic acid and 2,7-naphthalenedicarboxylic acid; and the like.

When n is 3, examples of the compound (L-1-2) include:

chain saturated tricarboxylic acids such as 1,2,3-propanetricarboxylic acid;

chain unsaturated tricarboxylic acids such as 1,2,3-propenetricarboxylic acid;

alicyclic tricarboxylic acids such as 1,2,4-cyclohexanetricarboxylic acid;

aromatic tricarboxylic acids such as trimellitic acid and 2,3,7-naphthalenetricarboxylic acid; and the like.

When n is 4, examples of the compound (L-1-2) include:

chain saturated tetracarboxylic acids such as 1,2,3,4-butanetetracarboxylic acid;

chain unsaturated tetracarboxylic acids such as 1,2,3,4-butadienetetracarboxylic acid;

alicyclic tetracarboxylic acids such as 1,2,5,6-cyclohexanetetracarboxylic acid and 2,3,5,6-norbornanetetracarboxylic acid;

aromatic tetracarboxylic acids such as pyromellitic acid and 2,3,6,7-naphthalenetetracarboxylic acid; and the like.

Of these, the compounds (L-1-2) in which n is 1 or 2 are preferred, the chain saturated monocarboxylic acid, the chain unsaturated monocarboxylic acid, the chain saturated dicarboxylic acid and the chain unsaturated monocarboxylic acid are more preferred, acetic acid, propionic acid, methacrylic acid, succinic acid, maleic acid and trans-2,3-dimethyl acrylic acid are still more preferred, the compounds (L-1-2) in which n is 1 are particularly preferred, and acetic acid, propionic acid, methacrylic acid and trans-2,3-dimethylacrylic acid are further particularly preferred.

In the compound (L-1-3), n is preferably 2 to 4.

When n is 2, examples of the compound (L-1-3) include:

chain diisocyanates such as ethylene diisocyanate, trimethylene diisocyanate, tetramethylene diisocyanate and hexamethylene diisocyanate;

alicyclic diisocyanates such as 1,4-cyclohexane diisocyanate and isophorone diisocyanate;

aromatic diisocyanates such as tolylene diisocyanate, 1,4-benzene diisocyanate and 4,4′-diphenylmethane diisocyanate; and the like.

When n is 3, examples of the compound (L-1-3) include:

chain triisocyanates such as trimethylene triisocyanate;

alicyclic triisocyanates such as 1,2,4-cyclohexane triisocyanate;

aromatic triisocyanates such as 1,2,4-benzene triisocyanate; and the like.

When n is 4, examples of the compound (L-1-3) include:

chain tetraisocyanates such as tetramethylene tetraisocyanate;

alicyclic tetraisocyanates such as 1,2,4,5-cyclohexane tetraisocyanate;

aromatic tetraisocyanates such as 1,2,4,5-benzene tetraisocyanate; and the like.

Of these, the compounds (L-1-3) in which n is 2 are preferred, the chain diisocyanates are more preferred, and hexamethylene diisocyanate is further preferred.

In the compound (L-1-4), n is preferably 2 to 4.

When n is 2, examples of the compound (L-1-4) include:

chain diamines such as ethylenediamine, N-methylethylenediamine, N,N′-dimethylethylenediamine, trimethylenediamine, N,N′-dimethyltrimethylenediamine, tetramethylenediamine and N,N′-dimethyltetramethylenediamine;

alicyclic diamines such as 1,4-cyclohexanediamine and 1,4-di(aminomethyl)cyclohexane;

aromatic diamines such as 1,4-diaminobenzene and 4,4′-diaminodiphenylmethane; and the like.

When n is 3, examples of the compound (L-1-4) include:

chain triamines such as triaminopropane and N,N′,N″-trimethyltriaminopropane;

alicyclic triamines such as 1,2,4-triaminocyclohexane;

aromatic triamines such as 1,2,4-triaminobenzene; and the like.

When n is 4, examples of the compound (L-1-4) include:

chain tetraamines such as tetraaminobutane;

alicyclic tetraamines such as 1,2,4,5-tetraaminocyclohexane and 2,3,5,6-tetraaminonorbomane;

aromatic tetraamines such as 1,2,4,5-tetraaminobenzene; and the like.

Of these, the compounds (L-1-4) in which n is 2 are preferred, chain diamines are more preferred, and N,N′-dimethylethylenediamine is further preferred.

The ligand compound (B2) is preferably the compound represented by the above formula (1), more preferably the compound represented by the above formula (L-1-2), still more preferably the monocarboxylic acid or the dicarboxylic acid, particularly preferably the saturated aliphatic monocarboxylic acid, the unsaturated aliphatic monocarboxylic acid, the aromatic monocarboxylic acid or the aromatic dicarboxylic acid, further particularly preferably the unsaturated aliphatic monocarboxylic acid, the aromatic monocarboxylic acid or the aromatic dicarboxylic acid, and most preferably (meth)acrylic acid, benzoic acid or phthalic acid.

The lower limit of the content of the aggregation inhibiting agent (B) with respect to the total solid content is preferably 0.001% by mass, more preferably 0.01% by mass, still more preferably 0.1% by mass, particularly preferably 1% by mass, further particularly preferably 4% by mass, and most preferably 8% by mass. The upper limit of the content is preferably 50% by mass, more preferably 30% by mass, still more preferably 20% by mass, and particularly preferably 15% by mass.

In the case in which the radiation-sensitive composition is the radiation-sensitive composition (I), the lower limit of the content of the aggregation inhibiting agent (B) with respect to 100 parts by mass of the particles (A) is preferably 0.001 parts by mass, more preferably 0.01 parts by mass, still more preferably 0.1 parts by mass, particularly preferably 1 part by mass, further particularly preferably 4 parts by mass, and most preferably 8 parts by mass. The upper limit of the content is preferably 50 parts by mass, more preferably 30 parts by mass, still more preferably 20 parts by mass, and particularly preferably 15 parts by mass.

In the case in which the radiation-sensitive composition is the radiation-sensitive composition (II), the lower limit of the content of the aggregation inhibiting agent (B) with respect to 100 parts by mass of the polymer (F) is preferably 0.001 parts by mass, more preferably 0.01 parts by mass, still more preferably 0.1 parts by mass, particularly preferably 1 part by mass, further particularly preferably 4 parts by mass, and most preferably 8 parts by mass. The upper limit of the content is preferably 50 parts by mass, more preferably 30 parts by mass, still more preferably 20 parts by mass, and particularly preferably 15 parts by mass.

When the content of the aggregation inhibiting agent (B) falls within the above range, the radiation-sensitive composition can exhibit more improved storage stability, and time-dependent deterioration of the LWR performance, resolution and sensitivity can be more inhibited.

### (C) Organic Solvent

The organic solvent (C) is not particularly limited as long as it is an organic solvent capable of dissolving or dispersing at least the particles (A) and the aggregation inhibiting agent (B), as well as optional component(s), etc., included as needed. The organic solvent (C) may be used either alone of one type, or in combination of two or more types thereof.

The organic solvent (C) is exemplified by alcohol solvents, ether solvents, ketone solvents, amide solvents, ester solvents, hydrocarbon solvents, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

C3-19 polyhydric alcohol partial ether solvents such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethyl acetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate;

and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the ester solvents and the ketone solvents are preferred, the polyhydric alcohol partial ether carboxylate solvents and the cyclic ketone solvents are more preferred, and propylene glycol monomethyl ether acetate and cyclohexanone are still more preferred.

### (D) Acid Generator

The acid generator (D) is a compound that generates an acid upon an irradiation with a radioactive ray. The action of the acid generated from the acid generator (D) causes: hydrolytic condensation, etc., of hydrolyzable groups with each other of a plurality of the particles (A) in the radiation-sensitive composition (I); or dissociation, etc., of the acid-labile group of the polymer (F) in the radiation-sensitive composition (II), thereby enabling the solubility of these in the developer solution to be changed, and as a result, pattern formation is enabled. The acid generator (D) may be contained in the radiation-sensitive composition in the form of: a low molecular compound (hereinafter, may be appropriately referred to as “(D) acid generating agent”); a part of the particles (A), the polymer (F) or the like incorporated therein; or a combination of the same.

The acid generating agent (D) is exemplified by an onium salt compound, an N-sulfonyloxyimide compound, a halogen-containing compound, a diazo ketone compound, and the like.

Exemplary onium salt compound may include a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantan-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethanesulfonyloxy)-1,8-naphthalimide, N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)-1,8-naphthalimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, N-(2-(3-tetracyclo[4.4.0.1^{2,5}.1^{7,10}]dodecanyl)-1,1-difluoroethanesulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, the acid generating agent (D) is preferably the onium salt compound or the N-sulfonyloxyimide compound, more preferably the sulfonium salt or the N-sulfonyloxyimide compound, still more preferably the triphenylsulfonium salt or the N-sulfonyloxyimide compound, and particularly preferably triphenylsulfonium nonafluoro-n-butane-1-sulfonate or N-(trifluoromethanesulfonyloxy)bicyclo[2.2.1]hept-5-ene-2,3-dicarboxyimide.

In the case in which the radiation-sensitive composition contains the acid generating agent (D), the lower limit of the content of the acid generating agent (D) with respect to the total solid content is preferably 1% by mass, more preferably 4% by mass, and still more preferably 8% by mass. The upper limit of the content is preferably 40% by mass, more preferably 30% by mass, and still more preferably 20% by mass.

In the case in which the radiation-sensitive composition is the radiation-sensitive composition (I), the lower limit of the content of the acid generating agent (D) with respect to 100 parts by mass of the particles (A) is preferably 1 part by mass, more preferably 4 parts by mass, and still more preferably 8 parts by mass. The upper limit of the content is preferably 40 parts by mass, more preferably 30 parts by mass, and still more preferably 20 parts by mass.

In the case in which the radiation-sensitive composition is the radiation-sensitive composition (II), the lower limit of the content of the acid generating agent (D) with respect to 100 parts by mass of the polymer (F) is preferably 1 part by mass, more preferably 4 parts by mass, and still more preferably 8 parts by mass. The upper limit of the content is preferably 40 parts by mass, more preferably 30 parts by mass, and still more preferably 20 parts by mass.

When the content of the acid generating agent (D) falls within the above range, the sensitivity, the LWR performance and the resolution of the radiation-sensitive composition can be more improved. The acid generator (D) may be used either alone of one type, or in combination of two or more types thereof.

### (E) Acid Diffusion Controller

The acid diffusion controller (E) controls in the film, a diffusion phenomenon of the acid generated from the acid generator (D) and the like upon an exposure, thereby achieving an effect of inhibiting an undesired chemical reaction in nonexposed regions. In addition, the radiation-sensitive composition may have more improved storage stability, and the resolution can be more improved. Furthermore, alteration of the pattern line width resulting from varying post exposure time delay, from the exposure until the development treatment, can be inhibited, thereby enabling the radiation-sensitive composition that is superior in process stability to be obtained. The acid diffusion controller (E) may be contained in the radiation-sensitive composition in the form of: a free compound (may be appropriately referred to as “(E) acid diffusion control agent” or “acid diffusion control agent (E)”); a part of the particles (A), the polymer (F) or the like incorporated therein; or a combination of the same.

The acid diffusion control agent (E) is exemplified by a compound represented by the following formula (L) (hereinafter, may be also referred to as “nitrogen-containing compound (I)”), a compound having two nitrogen atoms in one molecule (hereinafter, may be also referred to as “nitrogen-containing compound (II)”), a compound having three nitrogen atoms (hereinafter, may be also referred to as “nitrogen-containing compound (III)”), an amide group-containing compound, an urea compound, a nitrogen-containing heterocyclic compound, and the like.

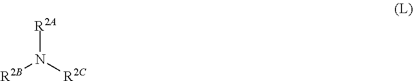

In the above formula (L), R^{2A}, R^{2B} and R^{2C} each independently represent a hydrogen atom, a substituted or unsubstituted alkyl group, a monovalent alicyclic saturated hydrocarbon group, an aryl group or an aralkyl group.

Examples of the nitrogen-containing compound (I) include: monoalkylamines such as n-hexylamine; dialkylamines such as di-n-butylamine; trialkylamines such as triethylamine; aromatic amines such as aniline; and the like.

Examples of the nitrogen-containing compound (II) include ethylenediamine, N,N,N′,N′-tetramethylethylenediamine, and the like.

Examples of the nitrogen-containing compound (III) include: polyamine compounds such as polyethyleneimine and polyallylamine; polymers such as dimethylaminoethylacrylamide; and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include: pyridines such as pyridine and 2-methylpyridine; morpholines such as N-propylmorpholine and N-(undecylcarbonyloxyethyl)morpholine; pyrazine; pyrazole; and the like.

Alternatively, a compound having an acid-labile group may be used as the nitrogen-containing heterocyclic compound. Examples of the nitrogen-containing heterocyclic compound having an acid-labile group include N-t-butoxycarbonylpiperidine, N-t-butoxycarbonylimidazole, N-t-butoxycarbonylbenzimidazole, N-t-butoxycarbonyl-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, N-t-amyloxycarbonyl-4-hydroxypiperidine, and the like.

As the acid diffusion control agent (E), a photodegradable base that generates a weak acid upon an irradiation with a radioactive ray may be used. The photodegradable base is exemplified by an onium salt compound that loses acid diffusion controllability through degradation upon an exposure, and the like. Examples of the onium salt compound include sulfonium salts represented by the following formula (K1), iodonium salts represented by the following formula (K2), and the like.

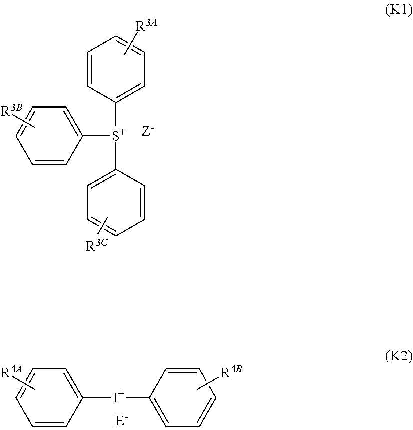

In the above formula (K1) and (K2), R^{3A}, R^{3B}, R^{3C}, R^{4A} and R^{4B} each independently represent a hydrogen atom, an alkyl group, an alkoxy group, a hydroxy group or a halogen atom; Z⁻ and E⁻ each represent OH⁻, R^{Y}—COO⁻, R^{Y}—SO₃⁻, R^{Y}—N⁻—SO₂—R^{Z} or an anion represented by the following formula (K3); R^{Y} represents an alkyl group, an aryl group or an aralkyl group; and R^{Z} represents an alkyl group or a fluorinated alkyl group.

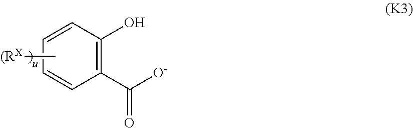

In the above formula (K3), R^{X} represents an alkyl group having 1 to 12 carbon atoms, a fluorinated alkyl group having 1 to 12 carbon atoms or an alkoxy group having 1 to 12 carbon atoms; and u is an integer of 0 to 2, wherein in the case in which u is 2, two R^{X}s may be identical or different.

Examples of the photodegradable base include compounds represented by the following formulae, and the like.

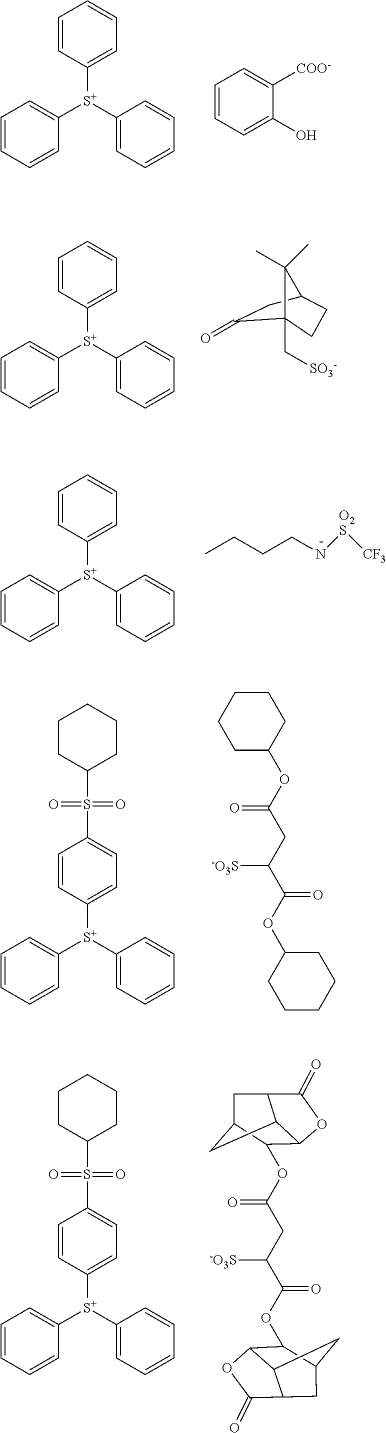

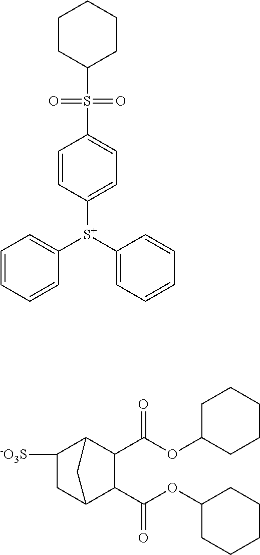

Of these, the photodegradable base is preferably a sulfonium salt, more preferably a triarylsulfonium salt, and still more preferably triphenylsulfonium salicylate.

In the case in which the radiation-sensitive composition contains the acid diffusion control agent (E), the lower limit of the content of the acid diffusion control agent (E) with respect to the total solid content is preferably 0.1% by mass, more preferably 0.3% by mass, and still more preferably 1% by mass. The upper limit of the content is preferably 20% by mass, more preferably 10% by mass, and still more preferably 5% by mass.

In the case in which the radiation-sensitive composition is the radiation-sensitive composition (I), the lower limit of the content of the acid diffusion control agent (E) with respect to 100 parts by mass of the particles (A) is preferably 0.1 parts by mass, more preferably 0.3 parts by mass, and still more preferably 1 part by mass. The upper limit of the content is preferably 20 parts by mass, more preferably 10 parts by mass, and still more preferably 5 parts by mass.

In the case in which the radiation-sensitive composition is the radiation-sensitive composition (II), the lower limit of the content of the acid diffusion control agent (E) with respect to 100 parts by mass of the polymer (F) is preferably 0.1 parts by mass, more preferably 0.3 parts by mass, and still more preferably 1 part by mass. The upper limit of the content is preferably 20 parts by mass, more preferably 10 parts by mass, and still more preferably 5 parts by mass.

When the content of the acid diffusion control agent (E) falls within the above range, the radiation-sensitive composition enables the LWR performance and the resolution to be more improved.

### (F) Polymer

The polymer (F) has an acid-labile group. The radiation-sensitive composition (II) typically contains the polymer (F). The polymer (F) typically has a structural unit that includes an acid-labile group (hereinafter, may be also referred to as “structural unit (I)”). According to the radiation-sensitive composition (I), the acid generated from the acid generator (D) or the like upon an irradiation with a radioactive ray results in dissociation of the acid-labile group in the polymer (F) at light-exposed regions, and thus a difference in solubility in a developer solution is caused between light-exposed regions and light-unexposed regions, thereby consequently enabling a pattern to be formed. The polymer (F) typically serves as a base polymer in the radiation-sensitive composition (I). The term “base polymer” as referred to herein means a polymer that is included in the greatest content of polymers constituting the pattern, and preferably, a polymer that accounts for no less than 50% by mass and more preferably no less than 60% by mass.

It is preferred that the polymer (F) also has a structural unit that includes a lactone structure, a cyclic carbonate structure, a sultone structure or a combination thereof (hereinafter, may be also referred to as “structural unit (II)”), a structural unit that includes a phenolic hydroxyl group (hereinafter, may be also referred to as “structural unit (III)”), and/or a structural unit that includes an alcoholic hydroxyl group (hereinafter, may be also referred to as “structural unit (IV)”) in addition to the structural unit (I). Additionally, the polymer (F) may have other structural unit than the structural units (I) to (IV). The polymer (F) may have one type or two or more types of these structural units. Each structural unit will be described below.

Structural Unit (I)

The structural unit (I) includes an acid-labile group. The structural unit (I) is exemplified by a structural unit represented by the following formula (2) (hereinafter, may be also referred to as “structural unit (I-1)”), and the like.

Structural Unit (I-1)

The structural unit (I-1) is a structural unit represented by the following formula (2).

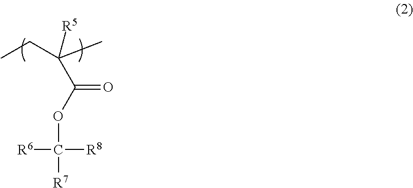

In the above formula (2), R⁵ represents a hydrogen atom, a fluorine atom, a methyl group or a trifluoromethyl group; R⁶ represents a monovalent hydrocarbon group having 1 to 20 carbon atoms; R⁷ and R⁸ each independently represent a monovalent hydrocarbon group having 1 to 20 carbon atoms, or the groups R⁷ and R⁸ taken together represent an alicyclic structure having 3 to 20 ring atoms together with the carbon atom to which R⁷ and R⁸ bond.

In light of the degree of copolymerization of the monomer that gives the structural unit (I-1), R⁵ represents preferably a hydrogen atom or a methyl group, and more preferably a methyl group.

Examples of the monovalent hydrocarbon group having 1 to 20 carbon atoms which may be represented by R⁶, R⁷ or R⁸ include groups similar to the hydrocarbon groups exemplified as R^{a1} and R^{a2} in the above formula (a) in connection with the aggregation inhibiting agent (B), and the like.

Examples of the alicyclic structure having 3 to 20 ring atoms which may be taken together represented by R⁷ and R⁸ together with the carbon atom to which R⁷ and R⁸ bond include:

monocyclic saturated alicyclic structures such as a cyclopropane structure, a cyclobutane structure, a cyclopentane structure, a cyclohexane structure, a cycloheptane structure and a cyclooctane structure;

polycyclic saturated alicyclic structures such as a norbornane structure, an adamantane structure, a tricyclodecane structure and a tetracyclododecane structure; and the like. Of these, a monocyclic saturated alicyclic structure having 5 to 8 ring atoms and a polycyclic saturated alicyclic structure having 7 to 12 ring atoms are preferred, a cyclopentane structure, a cyclohexane structure, a cyclooctane structure, a norbornane structure, an adamantane structure and a tetracyclododecane structure are more preferred, and a cyclopentane structure, an adamantane structure and a tetracyclododecane structure are still more preferred.

Examples of the structural unit (I-1) include structural units represented by the following formulae (2-1) to (2-6) (hereinafter, may be also referred to as “structural units (I-1-1) to (I-1-6)”), and the like.

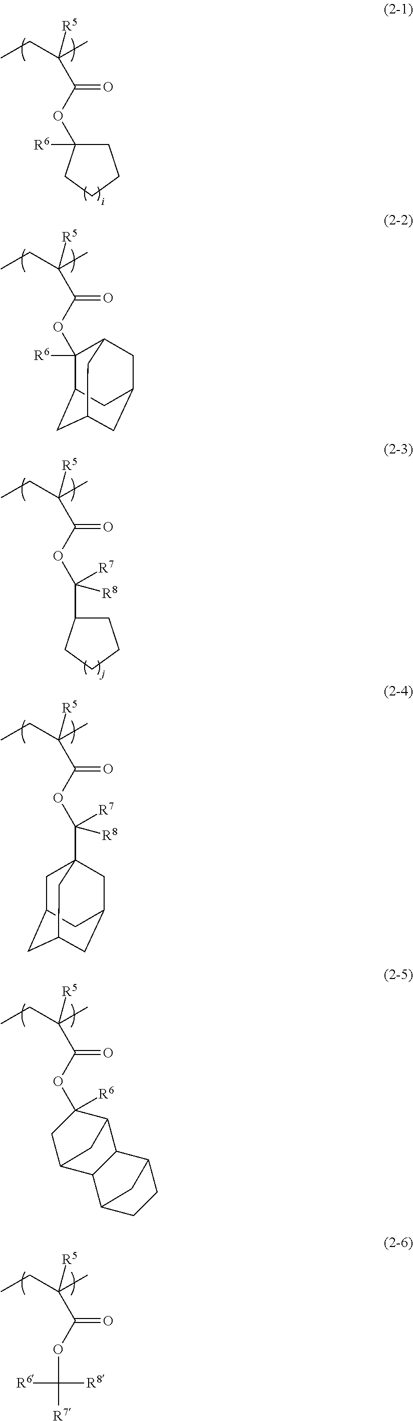

In the above formulae (2-1) to (2-6), R⁵ to R⁸ are as defined in the above formula (2).

In the above formula (2-1), i is an integer of 1 to 4.

In the above formula (2-3), j is an integer of 1 to 4.

In the above formula (2-6), R^{6′}, R^{7′} and R^{7′} each independently represent a monovalent hydrocarbon group having 1 to 20 carbon atoms.

In the above formulae, i and j are each preferably 1 to 3, and more preferably 1 or 2.

The structural unit (I) is preferably any of the structural units (I-1-1), (I-1-2), (I-1-4) and (I-1-5).

Examples of the structural unit (I-1) include structural units represented by the following formulae, and the like.

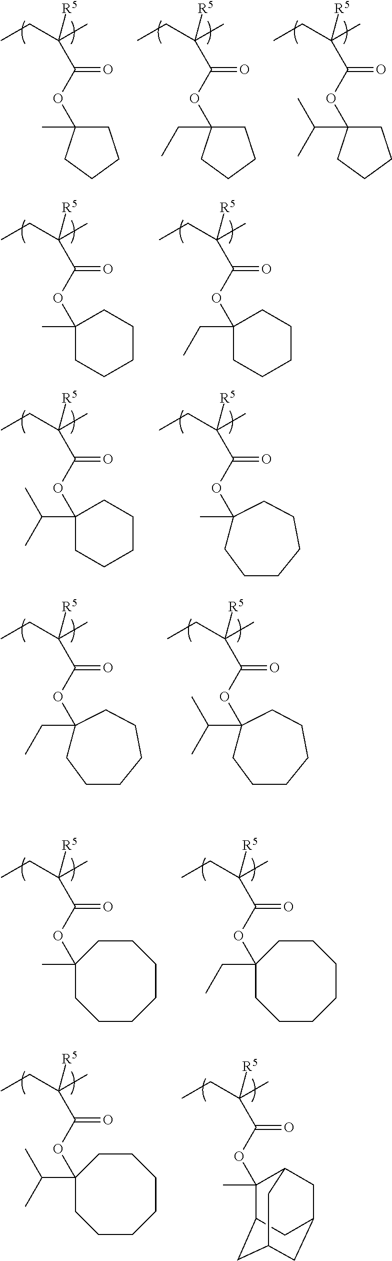

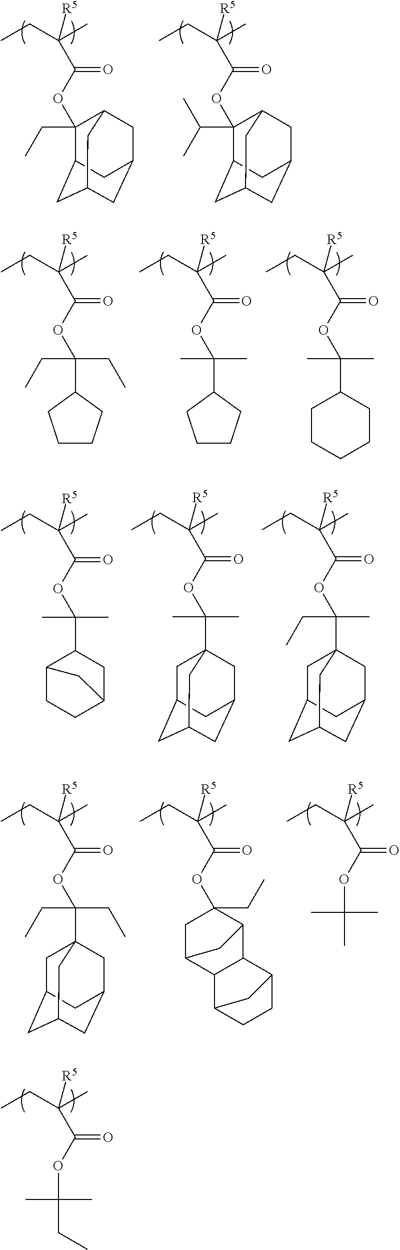

In the above formula, R⁵ is as defined in the above formula (2).

The structural unit (I) is preferably a structural unit derived from 1-alkyl-monocyclic saturated alicyclic-1-yl (meth)acrylate, a structural unit derived from 2-alkyl-polycyclic saturated alicyclic-2-yl (meth)acrylate or a structural unit derived from 2-(saturated alicyclic-yl)propane-2-yl (meth)acrylate, and more preferably a structural unit derived from 1-ethylcyclopentan-1-yl (meth)acrylate, a structural unit derived from 2-methyladamantan-2-yl (meth)acrylate, a structural unit derived from 2-ethyladamantan-2-yl (meth)acrylate, a structural unit derived from 2-ethyl-tetracyclododecan-2-yl (meth)acrylate and a structural unit derived from 2-(adamantan-1-yl)propane-2-yl (meth)acrylate.

The lower limit of the proportion of the structural unit (I) contained with respect to the total structural units constituting the polymer (F) is preferably 10 mol %, more preferably 20 mol %, still more preferably 30 mol %, and particularly preferably 40 mol %. The upper limit of the proportion is preferably 80 mol %, more preferably 70 mol %, still more preferably 60 mol %, and particularly preferably 55 mol %. When the proportion of the structural unit (I) contained falls within the above range, more improvements of the LWR performance, the resolution and the sensitivity of the radiation-sensitive composition are enabled.

Structural Unit (II)

The structural unit (II) includes a lactone structure, a cyclic carbonate structure, a sultone structure or a combination thereof. Due to further having the structural unit (II) in addition to the structural unit (I), the polymer (F) enables the solubility in a developer solution to be more appropriately adjusted, and as a result, more improvements of the LWR performance and the resolution of the radiation-sensitive composition are enabled. In addition, adhesiveness of the pattern formed from the radiation-sensitive composition to the substrate can be improved.

Examples of the structural unit (II) include structural units represented by the following formulae, and the like.

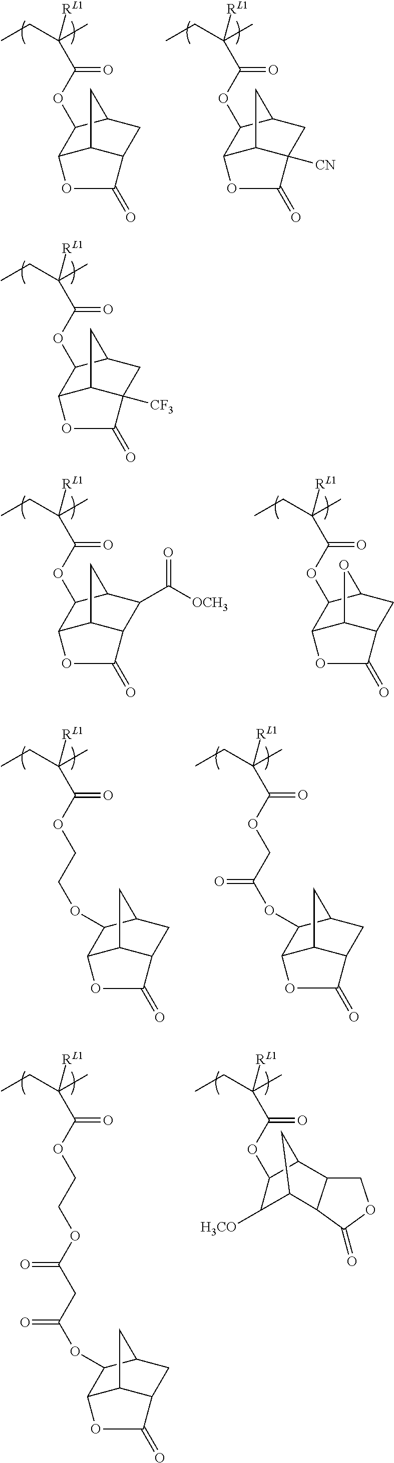

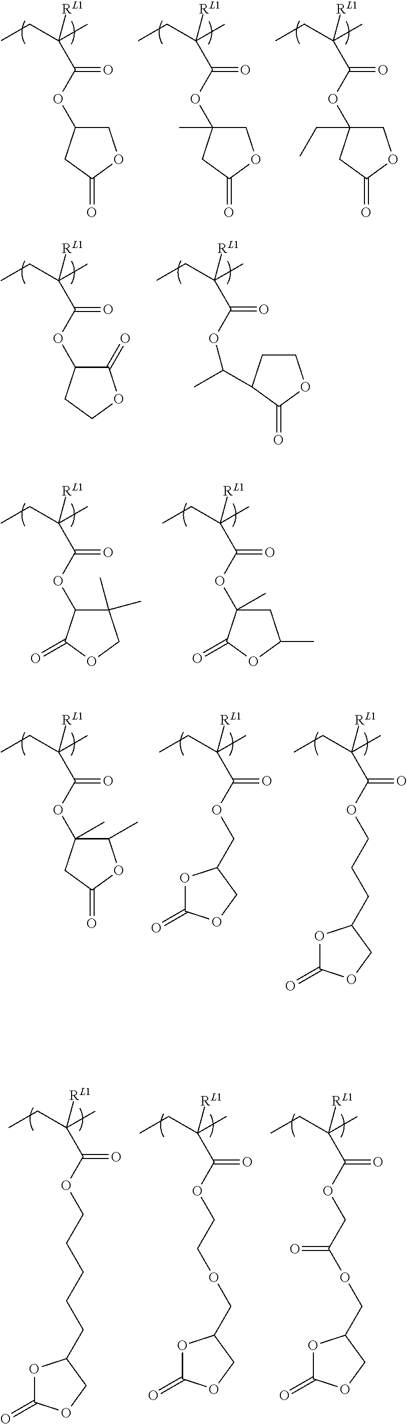

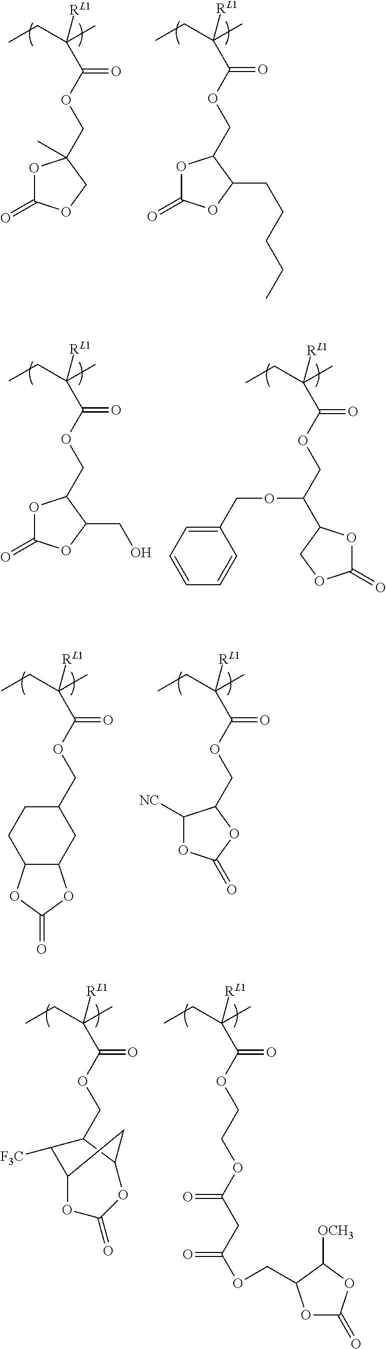

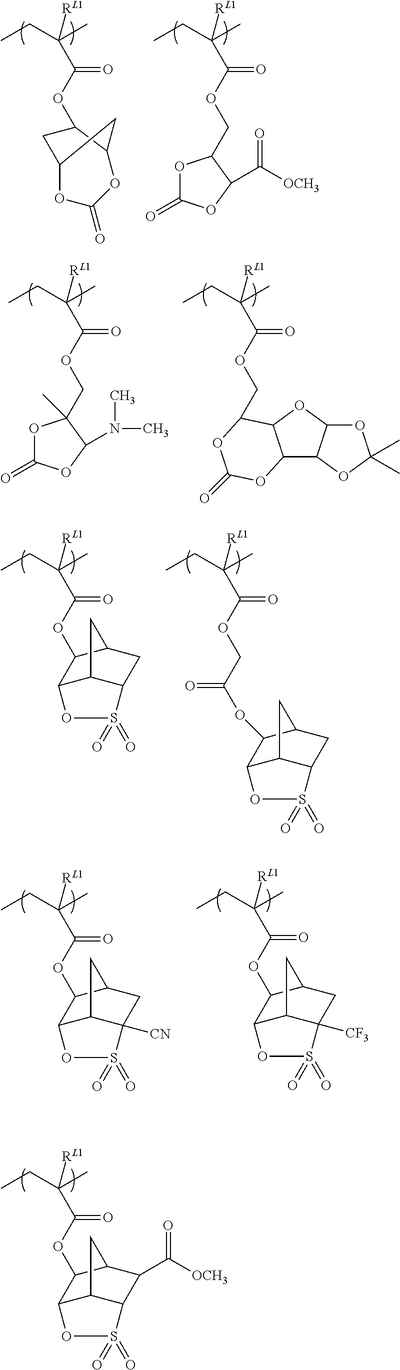

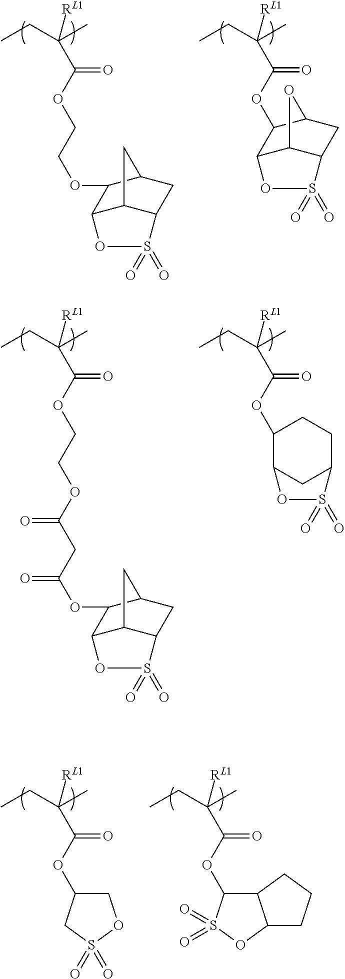

In the above formulae, R^{L1} represents a hydrogen atom, a fluorine atom, a methyl group or a trifluoromethyl group.

The structural unit (II) is preferably a structural unit having a lactone structure, more preferably a structural unit derived from lactone structure-containing (meth)acrylate, and still more preferably a structural unit derived from norbornanelactone-yl (meth)acrylate, a structural unit derived from cyanonorbomanelactone-yl (meth)acrylate, a structural unit derived from 7-oxynorbomanelactone-yl (meth)acrylate or a structural unit derived from γ-butyrolactone-yl (meth)acrylate.

In the case in which the polymer (F) has the structural unit (II), the lower limit of the proportion of the structural unit (II) contained with respect to the total structural units in the polymer (F) is preferably 10 mol %, more preferably 20 mol %, still more preferably 30 mol %, and particularly preferably 40 mol %. The upper limit of the proportion is preferably 80 mol %, more preferably 70 mol %, still more preferably 65 mol %, and particularly preferably 60 mol %. When the proportion of the structural unit (II) contained falls within the above range, the polymer (F) enables the solubility in a developer solution to be further appropriately adjusted, and as a result, further improvements of the LWR performance and the resolution of the radiation-sensitive composition are enabled. In addition, the adhesiveness of the resultant pattern to the substrate can be further improved.

Structural Unit (III)

The structural unit (III) includes a phenolic hydroxyl group. In a case in which a KrF excimer laser beam, EUV, an electron beam or the like is employed as the radioactive ray with which irradiation is conducted in the exposure step of the pattern-forming method, the polymer (F) having the structural unit (III) enables the sensitivity to be more improved.

The structural unit (III) is exemplified by a structural unit represented by the following formula (3) (hereinafter, may be also referred to as “structural unit (III-1)”), and the like.

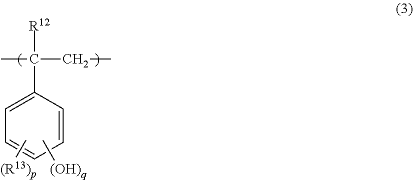

In the above formula (3), R¹² represents a hydrogen atom or a methyl group; R¹³ represents a monovalent organic group having 1 to 20 carbon atoms; p is an integer of 0 to 3, wherein in a case in which p is 2 or 3, a plurality of R¹³s may be identical or different; and q is an integer of 1 to 3, wherein the sum of p and q is no greater than 5.

In light of the copolymerizability of a monomer that gives the structural unit (III), R¹² represents preferably a hydrogen atom.

The monovalent organic group having 1 to 20 carbon atoms which is represented by R¹³ is exemplified by: a monovalent hydrocarbon group having 1 to 20 carbon atoms; a group (a) that includes a divalent hetero atom-containing group between two adjacent carbon atoms of the monovalent hydrocarbon group; a group obtained from the monovalent hydrocarbon group or the group (a) by substituting with a monovalent hetero atom-containing group a part or all of hydrogen atoms included therein; and the like.

Examples of the monovalent hydrocarbon group having 1 to 20 carbon atoms include similar groups to those exemplified as R⁶, R⁷ or R⁸ in the above formula (2), and the like.

Examples of the divalent hetero atom-containing group include —O—, —CO—, —S—, —CS—, —NR′—, groups obtained by combining at least two of the same, and the like, wherein R′ represents a hydrogen atom or a monovalent hydrocarbon group.

Examples of the monovalent hetero atom-containing group include: halogen atoms such as a fluorine atom, a chlorine atom, a bromine atom and an iodine atom; a hydroxy group, a carboxy group, a cyano group, an amino group, a sulfanyl group (—SH), and the like.

In the above formula (3), p is preferably an integer of 0 to 2, more preferably 0 or 1, and still more preferably 0.

In the above formula (3), q is preferably 1 or 2, and more preferably 1.

Examples of the structural unit (III-1) include structural units represented by the following formulae (3-1) to (3-4) (hereinafter, may be also referred to as “structural units (III-1-1) to (III-1-4)”), and the like.

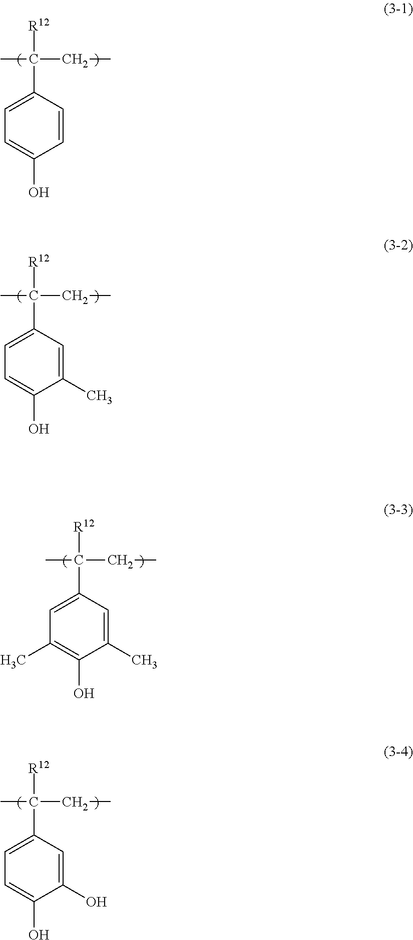

In the above formulae (3-1) to (3-4), R¹² is as defined in the above formula (3).

The structural unit (III) is preferably the structural unit (III-1), more preferably the structural unit (III-1-1) or the structural unit (III-1-2), and still more preferably the structural unit (III-1-1).

In the case in which the polymer (F) has the structural unit (III), the lower limit of the proportion of the structural unit (III) contained with respect to the total structural units constituting the polymer (F) is preferably 10 mol %, more preferably 20 mol %, still more preferably 30 mol %, and particularly preferably 40 mol %. The upper limit of the proportion is preferably 90 mol %, more preferably 80 mol %, still more preferably 70 mol %, and particularly preferably 60 mol %. When the proportion of the structural unit (III) falls within the above range, the radiation-sensitive composition enables the sensitivity to be further improved.

It is to be noted that the structural unit (III) may be formed by polymerizing, e.g., a monomer obtained by substituting a hydrogen atom of an —OH group in hydroxystyrene with an acetyl group or the like, and thereafter subjecting a thus resulting polymer to a hydrolysis reaction in the presence of a base such as an amine.

Structural Unit (IV)

The structural unit (IV) includes an alcoholic hydroxyl group. Due to having the structural unit (IV), the polymer (F) enables the solubility in a developer solution to be more appropriately adjusted, and as a result, more improvements of the LWR performance and the resolution of the radiation-sensitive composition are enabled. In addition, the adhesiveness of the pattern to the substrate can be more improved.

Examples of the structural unit (IV) include structural units represented by the following formulae, and the like.

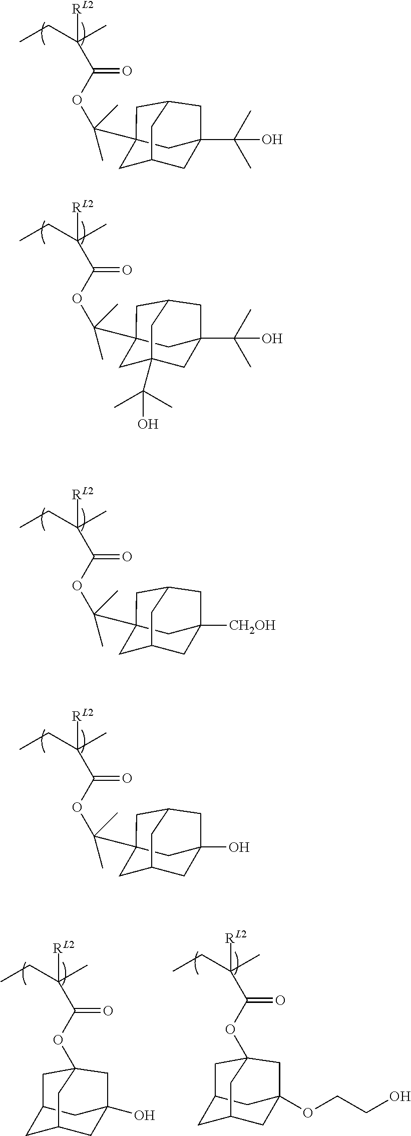

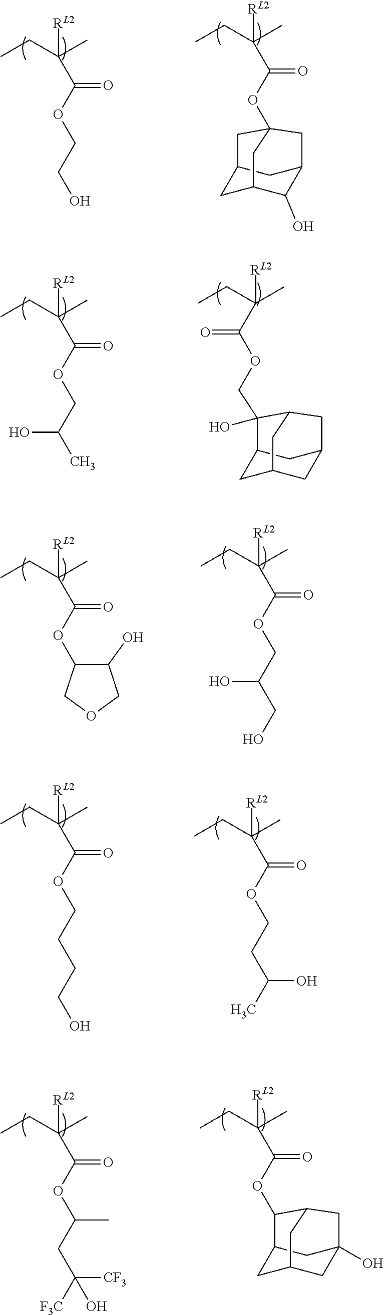

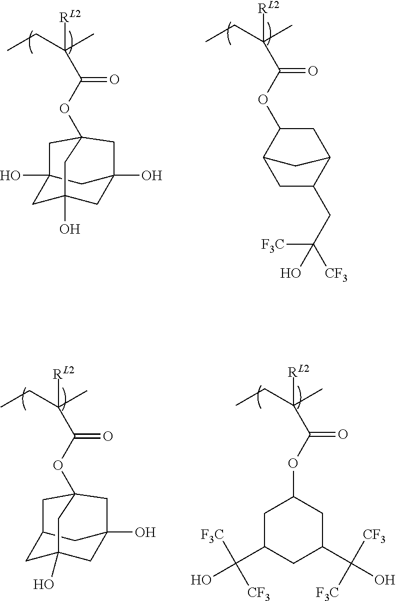

In the above formulae, R^{L2} represents a hydrogen atom, a fluorine atom, a methyl group or a trifluoromethyl group.

The structural unit (IV) is preferably a structural unit that includes a hydroxyadamantyl group, and more preferably a structural unit derived from 3-hydroxyadamantyl (meth)acrylate.

In the case in which the polymer (F) has the structural unit (IV), the lower limit of the proportion of the structural unit (IV) contained with respect to the total structural units constituting the polymer (F) is preferably 5 mol %, more preferably 10 mol %, still more preferably 15 mol %, and particularly preferably 20 mol %. The upper limit of the proportion is preferably 70 mol %, more preferably 60 mol %, still more preferably 50 mol %, and particularly preferably 40 mol %. When the proportion of the structural unit (IV) falls within the above range, the polymer (F) enables the solubility in a developer solution to be further appropriately adjusted, and as a result, further improvements of the LWR performance and the resolution of the radiation-sensitive composition are enabled. In addition, the adhesiveness of the pattern to the substrate can be further improved.

Other Structural Unit

The polymer (F) may have other structural unit in addition to the structural units (I) to (IV). The other structural unit is exemplified by a structural unit that includes a ketonic carbonyl group, a cyano group, a carboxy group, a nitro group, an amino group or a combination thereof, a structural unit derived from a (meth)acrylic acid ester that includes a nondissociable monovalent alicyclic hydrocarbon group, and the like. The upper limit of the proportion of the other structural unit contained with respect to the total structural units constituting the polymer (F) is preferably 20 mol %, and more preferably 10 mol %.

In the case in which the radiation-sensitive composition is the radiation-sensitive composition (II), the lower limit of the content of the polymer (F) with respect to the total solid content is preferably 70% by mass, more preferably 80% by mass, and still more preferably 85% by mass. The radiation-sensitive composition may include either only one type, or two or more types of the polymer (F).

Synthesis Method of Polymer (F)

The polymer (F) may be synthesized by, for example, polymerization of a monomer that gives each structural unit using a radical polymerization initiator or the like in an adequate solvent.

Examples of the radical polymerization initiator include:

azo-based radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate;

peroxide-based radical initiators such as benzoyl peroxide, t-butyl hydroperoxide and cumene hydroperoxide; and the like. Of these, AIBN and dimethyl 2,2′-azobisisobutyrate are preferred, and AIBN is more preferred. These radical polymerization initiators may be used either alone of one type, or in combination of two or more types thereof.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutane, bromohexane, dichloroethane, hexamethylene dibromide and chlorobenzene;

saturated carboxylic acid esters such as ethyl acetate, n-butyl acetate, i-butyl acetate and methyl propionate;

ketones such as acetone, methyl ethyl ketone, 4-methyl-2-pentanone and 2-heptanone;

ethers such as tetrahydrofuran, dimethoxyethane and diethoxyethane;

alcohols such as methanol, ethanol, 1-propanol, 2-propanol and 4-methyl-2-pentanol; and the like. These solvents for use in the polymerization may be used alone of one type, or two or more types thereof may be used.

The lower limit of the reaction temperature in the polymerization is preferably 40° C., and more preferably 50° C. The upper limit of the reaction temperature is preferably 150° C., and more preferably 120° C. The lower limit of the of the reaction time in the polymerization is preferably 1 hr, and more preferably 2 hrs. The upper limit of the reaction time is preferably 48 hrs, and more preferably 24 hrs.

The lower limit of the polystyrene equivalent weight average molecular weight (Mw) of the polymer (F) as determined by gel permeation chromatography (GPC) is preferably 1,000, more preferably 3,000, still more preferably 4,000, and particularly preferably 5,000. The upper limit of the Mw is preferably 50,000, more preferably 30,000, still more preferably 20,000, and particularly preferably 10,000. When the Mw of the polymer (F) falls within the above range, coating characteristics of the radiation-sensitive composition can be improved, and as a result, more improvements of the LWR performance and the resolution are enabled.

The lower limit of the ratio (Mw/Mn) of the Mw to the polystyrene equivalent number average molecular weight (Mn) as determined by GPC of the polymer (F) is typically 1, and preferably 1.1. The upper limit of the ratio is preferably 5, more preferably 3, still more preferably 2, and particularly preferably 1.5.

The Mw and the Mn of the polymer as referred to herein are values determined by using GPC under the following conditions.

GPC columns: for example, “G2000HXL”×2; “G3000HXL”×1; and “G4000HXL”×1, available from Tosoh Corporation

column temperature: 40° C.

elution solvent: tetrahydrofuran

flow rate: 1.0 mL/min

sample concentration: 1.0% by mass

amount of injected sample: 100 μL

detector: differential refractometer

standard substance: mono-dispersed polystyrene

### (G) Organic Acid

In the case in which the radiation-sensitive composition is the radiation-sensitive composition (I), owing to containing the organic acid (G), the radiation-sensitive composition (I) enables the change in solubility of the particles (A) in the developer solution after the irradiation with the radioactive ray to be more greater than that before the irradiation, and as a result, the sensitivity, the LWR performance and the resolution of the radiation-sensitive composition (I) can be more improved.

The organic acid (G) is exemplified by organic acids similar to those exemplified in connection with the component other than the metal atom constituting the metal oxide in the particles (A), and the like.

The organic acid (G) is preferably a carboxylic acid, more preferably a monocarboxylic acid or a dicarboxylic acid, and still more preferably methacrylic acid, acetic acid, trans-2,3-dimethyl acrylic acid or maleic acid.

The lower limit of the content of the organic acid (G) with respect to the total solid content is preferably 1% by mass, more preferably 5% by mass, and still more preferably 10% by mass. The upper limit of the content is preferably 90% by mass, more preferably 70% by mass, and still more preferably 50% by mass.

In the case in which the radiation-sensitive composition is the radiation-sensitive composition (I), the lower limit of the content of the organic acid (G) with respect to 100 parts by mass of the particles (A) is preferably 1 part by mass, more preferably 5 parts by mass, and still more preferably 10 parts by mass. The upper limit of the content is preferably 90 parts by mass, more preferably 70 parts by mass, and still more preferably 50 parts by mass.

When the content of the organic acid (G) falls within the above range, further improvements of the sensitivity, the LWR performance and the resolution of the radiation-sensitive composition are enabled. The radiation-sensitive composition may contain one type, or two or more types of the organic acid (G).

### Other Optional Component

The other optional component may be, for example, a surfactant, and the like. The other optional component may be used either alone of one type, or in combination of two or more types thereof.

The surfactant is a component that exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Tochem Products Co. Ltd.), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation of Radiation-Sensitive Resin Composition

The radiation-sensitive composition of the present embodiment may be prepared by, for example, mixing the particles (A), the aggregation inhibiting agent (B), the organic solvent (C), as well as the optional component such as the acid generator (D) as needed, at a certain ratio, preferably followed by filtering a mixture thus obtained through a filter having a pore size of 0.2 μm. The lower limit of the solid content concentration of the radiation-sensitive composition is preferably 0.1% by mass, more preferably 0.5% by mass, still more preferably 1% by mass, and particularly preferably 3% by mass. Meanwhile, the upper limit of the solid content concentration is preferably 50% by mass, more preferably 30% by mass, still more preferably 15% by mass, and particularly preferably 7% by mass.

### Pattern-Forming Method

The pattern-forming method of another embodiment of the present invention includes: applying the radiation-sensitive composition directly or indirectly on one face side of a substrate (hereinafter, may be also referred to as “applying step”); exposing the film obtained after the applying (hereinafter, may be also referred to as “exposure step”); and developing the film exposed (hereinafter, may be also referred to as “development step”). The radiation-sensitive composition of the embodiment of the present invention described above is employed in the pattern-forming method, and therefore the method enables a pattern superior in resolution to be formed with high sensitivity. In the following, each step is explained.

Applying Step

In this step, the radiation-sensitive composition is applied directly or indirectly on one face side of the substrate to form a film. Specifically, the film is formed by applying the radiation-sensitive composition such that the resulting film has a desired thickness, followed by prebaking (PB) to volatilize the solvent and the like in the radiation-sensitive composition as needed. A procedure for applying the radiation-sensitive composition is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film to be forming in the present step is preferably 1 nm, more preferably 5 nm, further more preferably 10 nm, and particularly preferably 20 nm. Meanwhile, the upper limit of the average thickness is preferably 1,000 nm, more preferably 200 nm, further more preferably 100 nm, and particularly preferably 70 nm.

The lower limit of the temperature of the PB is typically 60° C., and preferably 80° C. The upper limit of the temperature of the PB is typically 140° C., and preferably 120° C. The lower limit of the time period of the PB is typically 5 sec, and preferably 10 sec. The upper limit of the time period of the PB is typically 600 sec, and preferably 300 sec.

In this step, in order to inhibit an influence of basic impurities, etc., in the environmental atmosphere, for example, a protective film may be provided on the film formed. Furthermore, in the case of conducting liquid immersion lithography in the exposing step as described later, in order to avoid a direct contact between a liquid immersion medium and the film, a protective film for liquid immersion may also be provided on the film formed.

Exposure Step

In this step, the film obtained by the applying is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves such as visible light rays, ultraviolet rays, far ultraviolet rays, extreme ultraviolet rays (EUV; wavelength: 13.5 nm), X-rays and γ-rays; charged particle rays such as electron beams and α-rays; and the like. Of these, EUV and electron beams are preferred in light of increasing the secondary electrons generated from the metal-containing component (A) having absorbed the radioactive ray.

Development Step

In this step, the film exposed is developed by using a developer solution. A predetermined pattern is thereby formed. Examples of the developer solution include an alkaline aqueous solution, an organic solvent-containing liquid, and the like. In other words, the development step may be carried out by either development with an alkali or development with an organic solvent.

Examples of the alkaline aqueous solution include: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene; and the like.

The lower limit of a content of the alkaline compound in the alkaline aqueous solution is preferably 0.1% by mass, more preferably 0.5% by mass, and further more preferably 1% by mass. The upper limit of the content of the alkaline compound is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of an organic solvent in the organic solvent-containing liquid include organic solvents similar to those exemplified in connection with the organic solvent (C) in the radiation-sensitive composition, and the like. Of these, the ester solvent is preferred, and butyl acetate is more preferred.

The lower limit of a content of the organic solvent in the organic solvent-containing liquid is preferably 80% by mass, more preferably 90% by mass, further more preferably 95% by mass, and particularly preferably 99% by mass. When the content of the organic solvent falls within the above range, a more improvement of a contrast of the rate of dissolution in the developer solution between the light-exposed regions and the light-nonexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, and the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

It is preferred that, following the development, the substrate is rinsed by using a rinse agent such as water, alcohol, etc., and then dried. A procedure for the rinsing is exemplified by a procedure of continuously applying the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not in any way limited to these Examples. Various physical property values were determined according to the following methods.

### Weight Average Molecular Weight (Mw) and Number Average Molecular Weight (Mn)

The Mw and the Mn were determined by gel permeation chromatography (GPC) using GPC columns (“G2000HXL”×2, “G3000HXL”×1 and “G4000HXL”×1, Tosoh Corporation) under the analytical conditions involving a flow rate: 1.0 mL/min, an elution solvent: tetrahydrofuran, a sample concentration: 1.0% by mass, an amount of injected sample: 100 μL, a column temperature: 40° C., and a detector: differential refractometer, with mono-dispersed polystyrene as a standard. Moreover, the dispersity index (Mw/Mn) was calculated from the results of the determination of the Mw and the Mn.

Particle Diameter of Particles (A)

The particle diameter of the particles (A) synthesized was measured by using a light scattering measurement apparatus (“ALV-5000”, available from ALV-GmbH, Germany) under conditions involving a detection angle of 60° and a measurement time period of 120 sec.

### Synthesis of Particles (A)

### Synthesis Example 1: Synthesis of Particles (A-1)

Into a nitrogen-substituted 500-mL three-neck flask, 20.0 g (58.7 mmol) of tetrabutyl orthotitanate, 100 mL of tetrahydrofuran and 100 mL of methacrylic acid were placed, and then the mixture was heated to 65° C. After the mixture was stirred for 20 min, 10.6 g (587 mmol) of water was added dropwise over 10 min. After the mixture was stirred at 65° C. for 18 hrs, 10.6 g (587 mmol) of water was further added dropwise over 10 min. After the mixture was stirred for 2 hrs, the reaction was stopped by allowing to cool to normal temperature. Particles were precipitated by adding 400 mL of water to the reaction liquid obtained. Thus precipitated particles were subjected to centrifugal separation at 3,000 rpm for 10 min, and the supernatant was decanted. The residual particles were dissolved in 50 g of acetone, and 400 mL of water was added again to permit precipitation. The precipitated particles were subjected to centrifugal separation at 3,000 rpm, and the supernatant was decanted. The particles thus obtained were dried at 10 Pa for 15 hrs to give 11.2 g of particles (A-1) (yield: 56%).

### Synthesis Examples 2 to 6: Syntheses of Particles (A-2) to (A-6)

The particles (A-2) to (A-6) shown in Table 1 below were synthesized similarly to Synthesis Example 1 by using corresponding metal alkoxides.

### Synthesis Example 7: Synthesis of Particles (A-7)

Into a nitrogen-substituted 500-mL three-neck flask, 10.0 g of the particles (A-1) synthesized as described above, 100 mL of tetrahydrofuran and 30.0 g (24.6 mmol) of benzoic acid were placed, and then the mixture was stirred at room temperature for 24 hrs. Thereafter, 200 mL of water was added to precipitate the particles. To thus precipitated particles was added 25 g of acetone to permit dissolution, and the particles were precipitated by adding 200 mL of water. The particles precipitated were subjected to centrifugal separation at 3,000 rpm, and the supernatant was decanted. The particles thus obtained were dried at 10 Pa for 15 hrs to give 8.1 g of particles (A-7).

The measurements of yields (%) and particle diameters (nm) of the particles synthesized as described above are together shown in Table 1 below.

TABLE 1

| | | | Particle |
|---|---|---|---|
| (A) | Basic ingredient: | | diameter |
| Particles | Metal alkoxide | Yield (%) | (nm) |
| A-1 | Ti(OBu)₄ | 56 | 1.5 |
| A-2 | Zr(OiPr)₄ | 50 | 1.2 |
| A-3 | Hf(OiPr)₄ | 58 | 1.2 |
| A-4 | Ta(OBu)₄ | 52 | 2.2 |
| A-5 | W(OBu)₄ | 53 | 1.8 |
| A-6 | Sn(OBu)₄ | 55 | 1.6 |
| A-7 | — | 78 | 1.4 |

### Synthesis of Polymer (F)

Monomers used in syntheses of the polymers (F) are shown below.

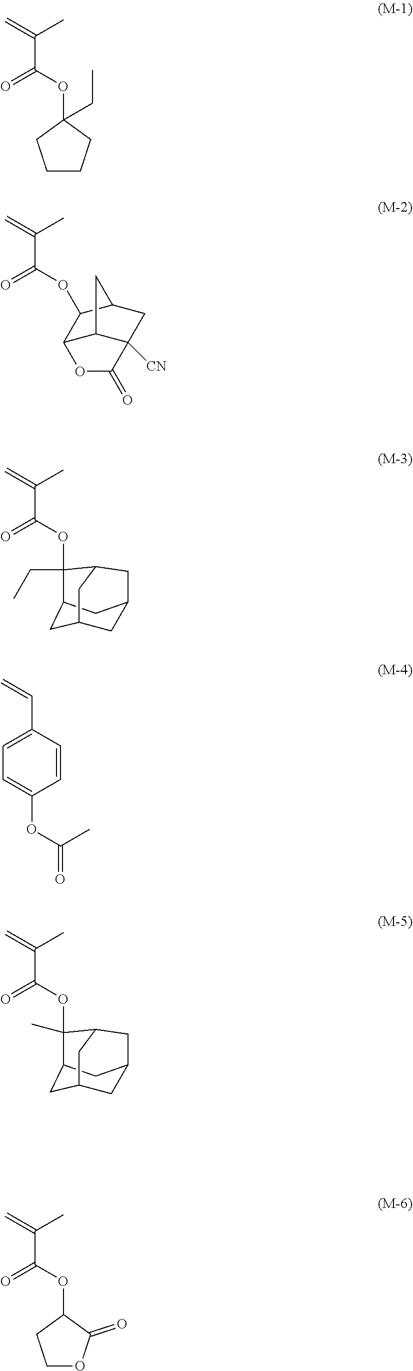 [SMILES: C=C(C)C(=O)OC1(CC)CCCC1 ; C=C(C)C(=O)OC1C2CC3C1OC(=O)C3(C#N)C2 ; C=C(C)C(=O)OC1(CC)C2CC3CC(C2)CC1C3 ; C=Cc1ccc(OC(C)=O)cc1 ; C=C(C)C(=O)OC1(C)C2CC3CC(C2)CC1C3 ; C=C(C)C(=O)OC1CCOC1=O]

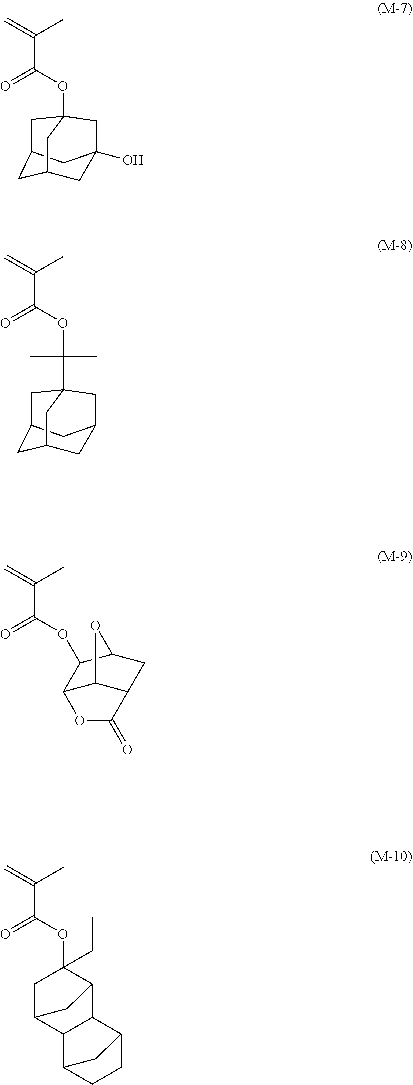

### Synthesis Example 8: Synthesis of Polymer (F-1)

A monomer solution was prepared by dissolving 7.97 g (35 mol %) of the compound (M-5), 7.44 g (45 mol %) of the compound (M-6) and 4.49 g (20 mol %) of the compound (M-7) in 40 g of 2-butanone, and 0.80 g (5 mol % with respect to a total of the monomers) of AIBN as a radical polymerization initiator was added thereto. Next, a 100-mL three-neck flask charged with 20 g of 2-butanone was purged with nitrogen for 30 min, and then heated to 80° C. with stirring. The above monomer solution prepared was added dropwise over 3 hrs by using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The cooled polymerization reaction mixture was charged into 400 g of methanol, and the precipitated white powder was filtered off. The collected white powder was washed twice with 80 g of methanol and filtered off, followed by drying at 50° C. for 12 hrs to synthesize a polymer (F-1) as a white powder (amount: 15.0 g; yield: 75%). The polymer (F-1) had the Mw of 7,200, and the Mw/Mn of 1.56. The results of the ¹³C-NMR analysis indicated that the proportions of the structural units derived from (M-5), (M-6) and (M-7) were 34.3 mol %, 45.0 mol % and 20.7 mol %, respectively.

### Synthesis Example 9: Synthesis of Polymer (F-2)

A monomer solution was prepared by dissolving 6.88 g (40 mol %) of the compound (M-1), 2.30 g (10 mol %) of the compound (M-8) and 10.83 g (50 mol %) of the compound (M-2) in 40 g of 2-butanone, and 0.72 g (5 mol % with respect to a total of the monomers) of AIBN as a radical polymerization initiator was added thereto. Next, a 100-mL three-neck flask charged with 20 g of 2-butanone was purged with nitrogen for 30 min, and then heated to 80° C. with stirring. The above monomer solution prepared was added dropwise over 3 hrs by using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The cooled polymerization reaction mixture was charged into 400 g of methanol, and the precipitated white powder was filtered off. The collected white powder was washed twice with 80 g of methanol and filtered off, followed by drying at 50° C. for 17 hrs to synthesize a polymer (F-2) as a white powder (amount: 14.8 g; yield: 74%). The polymer (F-2) had the Mw of 7,500, and the Mw/Mn of 1.53. The results of the ¹³C-NMR analysis indicated that the proportions of the structural units derived from (M-1), (M-8) and (M-2) were 40.2 mol %, 10.1 mol % and 49.7 mol %, respectively.

### Synthesis Example 10: Synthesis of Polymer (F-3)

A monomer solution was prepared by dissolving 3.43 g (20 mol %) of the compound (M-1), 3.59 g (15 mol %) of the compound (M-10), 7.83 g (40 mol %) of the compound (M-9) and 5.16 g (25 mol %) of the compound (M-7) in 40 g of 2-butanone, and 0.72 g (5 mol % with respect to a total of the monomers) of AIBN as a radical polymerization initiator was added thereto. Next, a 100-mL three-neck flask charged with 20 g of 2-butanone was purged with nitrogen for 30 min, and then heated to 80° C. with stirring. The above monomer solution prepared was added dropwise over 3 hrs by using a dropping funnel. The time of the start of the dropwise addition was regarded as the time of the start of the polymerization reaction, and the polymerization reaction was allowed to proceed for 6 hrs. After the completion of the polymerization reaction, the polymerization reaction mixture was water-cooled to 30° C. or below. The cooled polymerization reaction mixture was charged into 400 g of methanol, and the precipitated white powder was filtered off. The collected white powder was washed twice with 80 g of methanol and filtered off, followed by drying at 50° C. for 17 hrs to synthesize a polymer (F-3) as a white powder (amount: 15.3 g; yield: 77%). The polymer (F-3) had the Mw of 7,200, and the Mw/Mn of 1.53. The results of the ¹³C-NMR analysis indicated that the proportions of the structural units derived from (M-1), (M-10), (M-9) and (M-7) were 19.5 mol %, 15.5 mol %, 40.1 mol % and 24.9 mol %, respectively.

### Synthesis Example 11: Synthesis of Polymer (F-4)

After 55.0 g (65 mol %) of the compound (M-4) and 45.0 g (35 mol %) of the compound (M-3), 4 g of AIBN as a radical polymerization initiator, and 1 g of t-dodecyl mercaptan were dissolved in 100 g of propylene glycol monomethyl ether, the mixture was subjected to polymerization for 16 hrs in a nitrogen atmosphere, while the reaction temperature was maintained at 70° C. After the completion of the polymerization reaction, the polymerization reaction mixture was added dropwise to 1,000 g of n-hexane to permit solidification purification of a polymer. Thereafter, to the polymer was added 150 g of propylene glycol monomethyl ether again, and then 150 g of methanol, 34 g of triethylamine and 6 g of water were further added. The mixture was subjected to a hydrolysis reaction for 8 hrs while refluxing at a boiling point was allowed. After the completion of the reaction, the solvent and triethylamine were distilled off in vacuo, the resulting polymer was dissolved in 150 g of acetone, which was then added dropwise to 2,000 g of water to permit solidification, and the produced white powder was filtered off and was dried at 50° C. for 17 hrs to give a polymer (F-4) as a white powder (amount: 65.7 g; yield: 77%). The polymer (F-4) had the Mw of 7,500, and the Mw/Mn of 1.90. The result of ¹³C-NMR analysis indicated that the proportions of the structural unit derived from p-hydroxystyrene and the structural unit derived from (M-3) were 65.4 mol % and 34.6 mol %, respectively.

### Preparation of Radiation-Sensitive Composition

The aggregation inhibiting agent (B), the organic solvent (C), the acid generating agent (D) and the acid diffusion control agent (E) which were used in the preparation of the radiation-sensitive composition are shown below.

(B) Aggregation Inhibiting Agent

B-1: methacrylic acid

B-2: methacrylic anhydride

B-3: orthotriethyl formate

B-4: methacrylic acid chloride

B-5: benzoic acid

B-6: phthalic acid

B-7: acetic anhydride

B-8: benzoic acid chloride

(C) Organic Solvent

C-1: propylene glycol monomethyl ether acetate

C-2: cyclohexanone

(D) Acid Generating Agent

D-1: N-trifluoromethanesulfonyloxy-5-norbornene-2,3-dicarboxyimide (a compound represented by the following formula (D-1))

D-2: triphenylsulfonium nonafluoro-n-butane-1-sulfonate (a compound represented by the following formula (D-2))

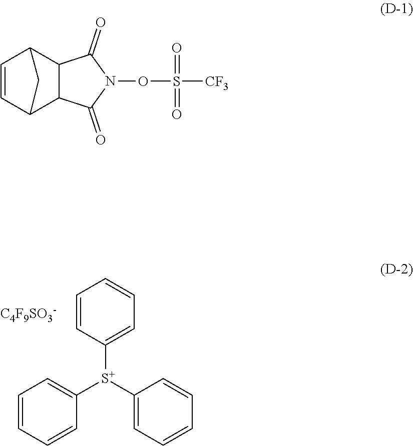 [SMILES: O=C1C2C3C=CC(C3)C2C(=O)N1OS(=O)(=O)C(F)(F)F ; "C4F9SO3-" ; c1ccc([S+](c2ccccc2)c2ccccc2)cc1]

(E) Acid Diffusion Control Agent

E-1: trioctylamine

E-2: triphenylsulfonium salicylate

### Preparation of Radiation-Sensitive Composition (I)

### Example 1

A radiation-sensitive composition (R1-1) was prepared by blending 100 parts by mass of (A-1) as the particles (A), 10 parts by mass of (B-1) as the aggregation inhibiting agent (B), 3,880 parts by mass of (C-1) as the organic solvent (C) and 10 parts by mass of (D-1) as the acid generating agent (D), and then filtering through a membrane filter having a pore size of 0.2 μm.

### Examples 2 to 20 and Comparative Examples 1 to 9

Radiation-sensitive compositions (R1-2) to (R1-20) and (CR1-1) to (CR1-9) were prepared by a similar operation to that of Example 1 except that the type and the content of each component used were as shown in Table 2 below. In Table 2, “-” indicates that the corresponding component was not used.

TABLE 2

| | | | | (B) | | | | | |
|---|---|---|---|---|---|---|---|---|---|
| | | | | Aggregation | | (C) | | | |
| | | | | inhibiting | | Organic | | (D) Acid | |
| | | (A) Particles | | agent | | solvent | | generating agent | |
| | Radiation- | | content | | content | | content | | content |
| | sensitive | | (parts by | | (parts by | | (parts by | | (parts by |
| | composition | type | mass) | type | mass) | type | mass) | type | mass) |
| Example 1 | R1-1 | A-1 | 100 | B-1 | 10 | C-1 | 3,880 | D-1 | 10 |
| Example 2 | R1-2 | A-2 | 100 | B-1 | 10 | C-1 | 3,880 | D-1 | 10 |
| Example 3 | R1-3 | A-3 | 100 | B-1 | 10 | C-1 | 3,880 | D-1 | 10 |
| Example 4 | R1-4 | A-4 | 100 | B-1 | 10 | C-1 | 3,880 | D-1 | 10 |
| Example 5 | R1-5 | A-5 | 100 | B-1 | 10 | C-1 | 3,880 | D-1 | 10 |
| Example 6 | R1-6 | A-6 | 100 | B-1 | 10 | C-1 | 3,880 | D-1 | 10 |
| Example 7 | R1-7 | A-7 | 100 | B-1 | 10 | C-1 | 3,880 | D-1 | 10 |
| Example 8 | R1-8 | A-1 | 100 | B-1 | 50 | C-1 | 3,880 | D-1 | 10 |
| Example 9 | R1-9 | A-1 | 100 | B-1 | 1 | C-1 | 3,880 | D-1 | 10 |
| Example 10 | R1-10 | A-1 | 100 | B-1 | 0.1 | C-1 | 3,880 | D-1 | 10 |
| Example 11 | R1-11 | A-1 | 100 | B-1 | 0.01 | C-1 | 3,880 | D-1 | 10 |
| Example 12 | R1-12 | A-1 | 100 | B-2 | 10 | C-1 | 3,880 | D-1 | 10 |
| Example 13 | R1-13 | A-1 | 100 | B-3 | 10 | C-1 | 3,880 | D-1 | 10 |
| Example 14 | R1-14 | A-1 | 100 | B-4 | 10 | C-1 | 3,880 | D-1 | 10 |
| Example 15 | R1-15 | A-1 | 100 | B-5 | 10 | C-1 | 3,880 | D-1 | 10 |
| Example 16 | R1-16 | A-1 | 100 | B-6 | 10 | C-1 | 3,880 | D-1 | 10 |
| Example 17 | R1-17 | A-1 | 100 | B-7 | 10 | C-1 | 3,880 | D-1 | 10 |
| Example 18 | R1-18 | A-1 | 100 | B-8 | 10 | C-1 | 3,880 | D-1 | 10 |
| Example 19 | R1-19 | A-1 | 100 | B-1 | 10 | C-1 | 3,880 | D-2 | 10 |
| Example 20 | R1-20 | A-1 | 100 | B-1 | 10 | C-1 | 3,880 | — | — |
| Comparative | CR1-1 | A-1 | 100 | — | — | C-1 | 3,880 | D-1 | 10 |
| Example 1 | | | | | | | | | |
| Comparative | CR1-2 | A-2 | 100 | — | — | C-1 | 3,880 | D-1 | 10 |
| Example 2 | | | | | | | | | |
| Comparative | CR1-3 | A-3 | 100 | — | — | C-1 | 3,880 | D-1 | 10 |
| Example 3 | | | | | | | | | |
| Comparative | CR1-4 | A-4 | 100 | — | — | C-1 | 3,880 | D-1 | 10 |
| Example 4 | | | | | | | | | |
| Comparative | CR1-5 | A-5 | 100 | — | — | C-1 | 3,880 | D-1 | 10 |
| Example 5 | | | | | | | | | |
| Comparative | CR1-6 | A-6 | 100 | — | — | C-1 | 3,880 | D-1 | 10 |
| Example 6 | | | | | | | | | |
| Comparative | CR1-7 | A-7 | 100 | — | — | C-1 | 3,880 | D-1 | 10 |
| Example 7 | | | | | | | | | |
| Comparative | CR1-8 | A-1 | 100 | — | — | C-1 | 3,880 | D-2 | 10 |
| Example 8 | | | | | | | | | |
| Comparative | CR1-9 | A-1 | 100 | — | — | C-1 | 3,880 | — | — |
| Example 9 | | | | | | | | | |

### Evaluations

The rate of dissolution of the formed film was measured by the following method on the radiation-sensitive composition (I) prepared as described above, and the rate of dissolution of the film was measured on the radiation-sensitive composition (I) stored for each time period. The storage stability of the radiation-sensitive composition (I) was evaluated from the measurements.

### Rate of Dissolution

The radiation-sensitive composition (I) prepared as described above was applied on the surface of a QCM substrate by using a spin coater for QCM (Litho Tech Japan Corporation), and PB was carried out at 90° C. for 60 sec. Thereafter, a film having an average thickness of 35 nm was formed through cooling at 23° C. for 30 sec. The rate of dissolution of the film (dissolution time period (sec)) was measured on thus formed film by using a resist development rate measuring apparatus (Litho Tech Japan Corporation, “RDA-Qz3”). The developer solution used was 2-propanol.

The sample of the radiation-sensitive composition subjected to the measurement as described above was stored at 5° C., and the rate of dissolution was measured 2 weeks later (T=2 w), 4 weeks later (T=4 w), 8 weeks later (T=8 w) and 12 weeks later (T=12 w). From the measurement results, the storage stability of the radiation-sensitive composition was evaluated.

TABLE 3

| | Radiation- | Dissolution time period (sec) | | | | |
|---|---|---|---|---|---|---|
| | sensitive | | | | | T = |
| | composition | T = 0 | T = 2 w | T = 4 w | T = 8 w | 12 w |
| Example 1 | R1-1 | 0.35 | 0.35 | 0.36 | 0.35 | 0.35 |
| Example 2 | R1-2 | 0.28 | 0.28 | 0.28 | 0.29 | 0.27 |
| Example 3 | R1-3 | 0.27 | 0.27 | 0.29 | 0.28 | 0.28 |
| Example 4 | R1-4 | 0.32 | 0.31 | 0.31 | 0.32 | 0.32 |
| Example 5 | R1-5 | 0.45 | 0.45 | 0.44 | 0.46 | 0.46 |
| Example 6 | R1-6 | 0.53 | 0.52 | 0.52 | 0.52 | 0.53 |
| Example 7 | R1-7 | 0.24 | 0.25 | 0.25 | 0.25 | 0.25 |
| Example 8 | R1-8 | 0.24 | 0.25 | 0.25 | 0.25 | 0.25 |
| Example 9 | R1-9 | 0.47 | 0.48 | 0.48 | 0.49 | 0.48 |
| Example 10 | R1-10 | 0.60 | 0.60 | 0.61 | 0.61 | 0.60 |
| Example 11 | R1-11 | 0.28 | 0.28 | 0.28 | 0.28 | 0.29 |
| Example 12 | R1-12 | 0.35 | 0.35 | 0.35 | 0.35 | 0.35 |
| Example 13 | R1-13 | 0.38 | 0.38 | 0.38 | 0.37 | 0.38 |
| Example 14 | R1-14 | 0.28 | 0.27 | 0.28 | 0.28 | 0.29 |
| Example 15 | R1-15 | 0.70 | 0.71 | 0.71 | 0.71 | 0.71 |
| Example 16 | R1-16 | 0.62 | 0.65 | 0.65 | 0.63 | 0.63 |
| Example 17 | R1-17 | 0.74 | 0.75 | 0.74 | 0.74 | 0.76 |
| Example 18 | R1-18 | 0.76 | 0.74 | 0.75 | 0.74 | 0.76 |
| Example 19 | R1-19 | 0.35 | 0.35 | 0.36 | 0.33 | 0.35 |
| Example 20 | R1-20 | 0.32 | 0.31 | 0.32 | 0.33 | 0.32 |
| Comparative | CR1-1 | 0.61 | 0.68 | 0.77 | 1.21 | 1.58 |
| Example 1 | | | | | | |
| Comparative | CR1-2 | 1.02 | 1.22 | 1.75 | 4.50 | 7.23 |
| Example 2 | | | | | | |
| Comparative | CR1-3 | 0.95 | 1.23 | 1.82 | 4.72 | 7.66 |
| Example 3 | | | | | | |
| Comparative | CR1-4 | 0.63 | 0.72 | 0.99 | 1.35 | 4.23 |
| Example 4 | | | | | | |
| Comparative | CR1-5 | 0.93 | 1.12 | 1.56 | 2.83 | 4.01 |
| Example 5 | | | | | | |
| Comparative | CR1-6 | 1.12 | 1.32 | 2.26 | 4.70 | 8.24 |
| Example 6 | | | | | | |
| Comparative | CR1-7 | 0.48 | 0.68 | 1.21 | 2.35 | 3.88 |
| Example 7 | | | | | | |
| Comparative | CR1-8 | 0.65 | 0.72 | 0.89 | 1.33 | 1.71 |
| Example 8 | | | | | | |
| Comparative | CR1-9 | 0.78 | 0.98 | 1.41 | 1.94 | 2.53 |
| Example 9 | | | | | | |

As is clear from the results shown in Table 3, the rates of dissolution in the developer solution of the radiation-sensitive compositions of Examples exhibited less time-dependent alteration than the radiation-sensitive compositions of Comparative Examples.

Resist Pattern Formation (1): Development with Alkali

The radiation-sensitive composition (I) prepared as described above was applied on the surface of an 8-inch silicon wafer by using a spin coater (“CLEAN TRACK ACTS”, available from Tokyo Electron Limited), and PB was carried out at 90° C. for 60 sec. Thereafter, a film having an average thickness of 35 nm was forming through cooling at 23° C. for 30 sec. Next, the film was irradiated with an electron beam by using a simplified electron beam writer (“HL800D” available from Hitachi, Ltd.; output: 50 KeV, electric current density: 5.0 A/cm²). Then, a development was carried out at 23° C. for 30 sec with a 2.38% by mass aqueous TMAH solution as a developer solution, followed by drying to form a positive-tone pattern.

Resist Pattern Formation (2): Development with Organic Solvent

A negative-tone pattern was formed by a similar operation to that of the Resist Pattern Formation (1) except that a development with an organic solvent was carried out using n-butyl acetate in place of the aqueous TMAH solution, and that washing with water was not conducted.

### Evaluations

According to the following methods, the LWR performance, the resolution and the sensitivity were determined on each of the radiation-sensitive compositions stored at 5° C., 2 weeks later (T=2 w), 4 weeks later (T=4 w), 8 weeks later (T=8 w) and 12 weeks later (T=12 w) as described above. The results of the evaluations are shown in Tables 4 and 5. For the measurement of the pattern line-width, a scanning electron microscope (“S-9380”, available from Hitachi High-Technologies Corporation) was used.

LWR Performance

The pattern was observed from above by using the scanning electron microscope. The line width was measured at arbitrary 50 points in total, then a 3-Sigma value was determined from the distribution of the measurements, and the value was defined as “LWR performance (nm)”. The smaller value indicates a better LWR performance. Each LWR performance value was compared to the value on the radiation-sensitive composition of T=0 (baseline) shown in Tables 4 and 5, and the LWR performance was evaluated to be: “equivalent (equiv.)” when the change was less than 10% (the LWR performance value being greater than 90% and less than 110%); and “unfavorable (unfav.)” when worsen by no less than 10% (the LWR performance value being no less than 110%).

Resolution

A dimension of the minimum resist pattern formed was measured, and the measurement value was defined as “resolution (nm)”. The smaller value indicates a better resolution. Each resolution value was compared to the value on the radiation-sensitive composition of T=0 (baseline) shown in Tables 4 and 5, and the resolution was evaluated to be: “equivalent (equiv.)” when the change was less than 10% (the resolution value being greater than 90% and less than 110%); and “unfavorable (unfav.)” when worsen by no less than 10% (the resolution value being no less than 110%).

Sensitivity

An exposure dose required for forming a line-and-space pattern of 150 nm was measured, and the measurement value was defined as “sensitivity (μC)”. The smaller value indicates a better sensitivity. Each sensitivity value was compared to the value on the radiation-sensitive composition of T=0 (baseline) shown in Tables 4 and 5, and the sensitivity was evaluated to be: “equivalent (equiv.)” when the change was less than 10% (the sensitivity value being greater than 90% and less than 110%); and “unfavorable (unfav.)” when the change was no less than 10% (the sensitivity value being less than 90% or no less than 110%).

TABLE 4

| | Radiation- | Development with alkali | | | | | | |
|---|---|---|---|---|---|---|---|---|
| | sensitive | LWR performance | | | | | Resolution | |
| | composition | T = 0 | T = 2 w | T = 4 w | T = 8 w | T = 12 w | T = 0 | T = 2 w |
| Example 1 | R1-1 | baseline | equiv. | equiv. | equiv. | equiv. | baseline | equiv. |
| Example 2 | R1-2 | baseline | equiv. | equiv. | equiv. | equiv. | baseline | equiv. |
| Example 3 | R1-3 | baseline | equiv. | equiv. | equiv. | equiv. | baseline | equiv. |
| Example 4 | R1-4 | baseline | equiv. | equiv. | equiv. | equiv. | baseline | equiv. |
| Example 5 | R1-5 | baseline | equiv. | equiv. | equiv. | equiv. | baseline | equiv. |
| Example 6 | R1-6 | baseline | equiv. | equiv. | equiv. | equiv. | baseline | equiv. |
| Example 7 | R1-7 | baseline | equiv. | equiv. | equiv. | equiv. | baseline | equiv. |
| Example 8 | R1-8 | baseline | equiv. | equiv. | equiv. | equiv. | baseline | equiv. |
| Example 9 | R1-9 | baseline | equiv. | equiv. | equiv. | equiv. | baseline | equiv. |
| Example 10 | R1-10 | baseline | equiv. | equiv. | equiv. | equiv. | baseline | equiv. |
| Example 11 | R1-11 | baseline | equiv. | equiv. | equiv. | equiv. | baseline | equiv. |
| Example 12 | R1-12 | baseline | equiv. | equiv. | equiv. | equiv. | baseline | equiv. |
| Example 13 | R1-13 | baseline | equiv. | equiv. | equiv. | equiv. | baseline | equiv. |
| Example 14 | R1-14 | baseline | equiv. | equiv. | equiv. | equiv. | baseline | equiv. |
| Example 15 | R1-15 | baseline | equiv. | equiv. | equiv. | equiv. | baseline | equiv. |
| Example 16 | R1-16 | baseline | equiv. | equiv. | equiv. | equiv. | baseline | equiv. |
| Example 17 | R1-17 | baseline | equiv. | equiv. | equiv. | equiv. | baseline | equiv. |
| Example 18 | R1-18 | baseline | equiv. | equiv. | equiv. | equiv. | baseline | equiv. |
| Example 19 | R1-19 | baseline | equiv. | equiv. | equiv. | equiv. | baseline | equiv. |
| Example 20 | R1-20 | baseline | equiv. | equiv. | equiv. | equiv. | baseline | equiv. |
| Comparative | CR1-1 | baseline | unfav. | unfav. | unfav. | unfav. | baseline | unfav. |
| Example 1 | | | | | | | | |
| Comparative | CR1-2 | baseline | unfav. | unfav. | unfav. | unfav. | baseline | unfav. |
| Example 2 | | | | | | | | |
| Comparative | CR1-3 | baseline | unfav. | unfav. | unfav. | unfav. | baseline | unfav. |
| Example 3 | | | | | | | | |
| Comparative | CR1-4 | baseline | unfav. | unfav. | unfav. | unfav. | baseline | unfav. |
| Example 4 | | | | | | | | |
| Comparative | CR1-5 | baseline | unfav. | unfav. | unfav. | unfav. | baseline | unfav. |
| Example 5 | | | | | | | | |
| Comparative | CR1-6 | baseline | unfav. | unfav. | unfav. | unfav. | baseline | unfav. |
| Example 6 | | | | | | | | |
| Comparative | CR1-7 | baseline | unfav. | unfav. | unfav. | unfav. | baseline | unfav. |
| Example 7 | | | | | | | | |
| Comparative | CR1-8 | baseline | unfav. | unfav. | unfav. | unfav. | baseline | unfav. |
| Example 8 | | | | | | | | |
| Comparative | CR1-9 | baseline | unfav. | unfav. | unfav. | unfav. | baseline | unfav. |
| Example 9 | | | | | | | | |

| | Development with alkali | | | | | | | |
|---|---|---|---|---|---|---|---|---|
| | Resolution | | | Sensitivity | | | | |
| | T = 4 w | T = 8 w | T = 12 w | T = 0 | T = 2 w | T = 4 w | T = 8 w | T = 12 w |
| Example 1 | equiv. | equiv. | equiv. | baseline | equiv. | equiv. | equiv. | equiv. |
| Example 2 | equiv. | equiv. | equiv. | baseline | equiv. | equiv. | equiv. | equiv. |
| Example 3 | equiv. | equiv. | equiv. | baseline | equiv. | equiv. | equiv. | equiv. |
| Example 4 | equiv. | equiv. | equiv. | baseline | equiv. | equiv. | equiv. | equiv. |
| Example 5 | equiv. | equiv. | equiv. | baseline | equiv. | equiv. | equiv. | equiv. |
| Example 6 | equiv. | equiv. | equiv. | baseline | equiv. | equiv. | equiv. | equiv. |
| Example 7 | equiv. | equiv. | equiv. | baseline | equiv. | equiv. | equiv. | equiv. |
| Example 8 | equiv. | equiv. | equiv. | baseline | equiv. | equiv. | equiv. | equiv. |
| Example 9 | equiv. | equiv. | equiv. | baseline | equiv. | equiv. | equiv. | equiv. |
| Example 10 | equiv. | equiv. | equiv. | baseline | equiv. | equiv. | equiv. | equiv. |
| Example 11 | equiv. | equiv. | equiv. | baseline | equiv. | equiv. | equiv. | equiv. |
| Example 12 | equiv. | equiv. | equiv. | baseline | equiv. | equiv. | equiv. | equiv. |
| Example 13 | equiv. | equiv. | equiv. | baseline | equiv. | equiv. | equiv. | equiv. |
| Example 14 | equiv. | equiv. | equiv. | baseline | equiv. | equiv. | equiv. | equiv. |
| Example 15 | equiv. | equiv. | equiv. | baseline | equiv. | equiv. | equiv. | equiv. |
| Example 16 | equiv. | equiv. | equiv. | baseline | equiv. | equiv. | equiv. | equiv. |
| Example 17 | equiv. | equiv. | equiv. | baseline | equiv. | equiv. | equiv. | equiv. |
| Example 18 | equiv. | equiv. | equiv. | baseline | equiv. | equiv. | equiv. | equiv. |
| Example 19 | equiv. | equiv. | equiv. | baseline | equiv. | equiv. | equiv. | equiv. |
| Example 20 | equiv. | equiv. | equiv. | baseline | equiv. | equiv. | equiv. | equiv. |
| Comparative | unfav. | unfav. | unfav. | baseline | unfav. | unfav. | unfav. | unfav. |
| Example 1 | | | | | | | | |
| Comparative | unfav. | unfav. | unfav. | baseline | unfav. | unfav. | unfav. | unfav. |
| Example 2 | | | | | | | | |
| Comparative | unfav. | unfav. | unfav. | baseline | unfav. | unfav. | unfav. | unfav. |
| Example 3 | | | | | | | | |
| Comparative | unfav. | unfav. | unfav. | baseline | unfav. | unfav. | unfav. | unfav. |
| Example 4 | | | | | | | | |
| Comparative | unfav. | unfav. | unfav. | baseline | unfav. | unfav. | unfav. | unfav. |
| Example 5 | | | | | | | | |
| Comparative | unfav. | unfav. | unfav. | baseline | unfav. | unfav. | unfav. | unfav. |
| Example 6 | | | | | | | | |
| Comparative | unfav. | unfav. | unfav. | baseline | unfav. | unfav. | unfav. | unfav. |
| Example 7 | | | | | | | | |
| Comparative | unfav. | unfav. | unfav. | baseline | unfav. | unfav. | unfav. | unfav. |
| Example 8 | | | | | | | | |
| Comparative | unfav. | unfav. | unfav. | baseline | unfav. | unfav. | unfav. | unfav. |
| Example 9 | | | | | | | | |

TABLE 5

| | Radiation- | Development with organic solvent | | | | | | |
|---|---|---|---|---|---|---|---|---|
| | sensitive | LWR performance | | | | | Resolution | |
| | composition | T = 0 | T = 2 w | T = 4 w | T = 8 w | T = 12 w | T = 0 | T = 2 w |
| Example 1 | R1-1 | baseline | equiv. | equiv. | equiv. | equiv. | baseline | equiv. |
| Example 2 | R1-2 | baseline | equiv. | equiv. | equiv. | equiv. | baseline | equiv. |
| Example 3 | R1-3 | baseline | equiv. | equiv. | equiv. | equiv. | baseline | equiv. |
| Example 4 | R1-4 | baseline | equiv. | equiv. | equiv. | equiv. | baseline | equiv. |
| Example 5 | R1-5 | baseline | equiv. | equiv. | equiv. | equiv. | baseline | equiv. |
| Example 6 | R1-6 | baseline | equiv. | equiv. | equiv. | equiv. | baseline | equiv. |
| Example 7 | R1-7 | baseline | equiv. | equiv. | equiv. | equiv. | baseline | equiv. |
| Example 8 | R1-8 | baseline | equiv. | equiv. | equiv. | equiv. | baseline | equiv. |
| Example 9 | R1-9 | baseline | equiv. | equiv. | equiv. | equiv. | baseline | equiv. |
| Example 10 | R1-10 | baseline | equiv. | equiv. | equiv. | equiv. | baseline | equiv. |
| Example 11 | R1-11 | baseline | equiv. | equiv. | equiv. | equiv. | baseline | equiv. |
| Example 12 | R1-12 | baseline | equiv. | equiv. | equiv. | equiv. | baseline | equiv. |
| Example 13 | R1-13 | baseline | equiv. | equiv. | equiv. | equiv. | baseline | equiv. |
| Example 14 | R1-14 | baseline | equiv. | equiv. | equiv. | equiv. | baseline | equiv. |
| Example 15 | R1-15 | baseline | equiv. | equiv. | equiv. | equiv. | baseline | equiv. |
| Example 16 | R1-16 | baseline | equiv. | equiv. | equiv. | equiv. | baseline | equiv. |
| Example 17 | R1-17 | baseline | equiv. | equiv. | equiv. | equiv. | baseline | equiv. |
| Example 18 | R1-18 | baseline | equiv. | equiv. | equiv. | equiv. | baseline | equiv. |
| Example 19 | R1-19 | baseline | equiv. | equiv. | equiv. | equiv. | baseline | equiv. |
| Example 20 | R1-20 | baseline | equiv. | equiv. | equiv. | equiv. | baseline | equiv. |
| Comparative | CR1-1 | baseline | unfav. | unfav. | unfav. | unfav. | baseline | unfav. |
| Example 1 | | | | | | | | |
| Comparative | CR1-2 | baseline | unfav. | unfav. | unfav. | unfav. | baseline | unfav. |
| Example 2 | | | | | | | | |
| Comparative | CR1-3 | baseline | unfav. | unfav. | unfav. | unfav. | baseline | unfav. |
| Example 3 | | | | | | | | |
| Comparative | CR1-4 | baseline | unfav. | unfav. | unfav. | unfav. | baseline | unfav. |
| Example 4 | | | | | | | | |
| Comparative | CR1-5 | baseline | unfav. | unfav. | unfav. | unfav. | baseline | unfav. |
| Example 5 | | | | | | | | |
| Comparative | CR1-6 | baseline | unfav. | unfav. | unfav. | unfav. | baseline | unfav. |
| Example 6 | | | | | | | | |
| Comparative | CR1-7 | baseline | unfav. | unfav. | unfav. | unfav. | baseline | unfav. |
| Example 7 | | | | | | | | |
| Comparative | CR1-8 | baseline | unfav. | unfav. | unfav. | unfav. | baseline | unfav. |
| Example 8 | | | | | | | | |
| Comparative | CR1-9 | baseline | unfav. | unfav. | unfav. | unfav. | baseline | unfav. |
| Example 9 | | | | | | | | |

| | Development with organic solvent | | | | | | | |
|---|---|---|---|---|---|---|---|---|
| | Resolution | | | Sensitivity | | | | |
| | T = 4 w | T = 8 w | T = 12 w | T = 0 | T = 2 w | T = 4 w | T = 8 w | T = 12 w |
| Example 1 | equiv. | equiv. | equiv. | baseline | equiv. | equiv. | equiv. | equiv. |
| Example 2 | equiv. | equiv. | equiv. | baseline | equiv. | equiv. | equiv. | equiv. |
| Example 3 | equiv. | equiv. | equiv. | baseline | equiv. | equiv. | equiv. | equiv. |
| Example 4 | equiv. | equiv. | equiv. | baseline | equiv. | equiv. | equiv. | equiv. |
| Example 5 | equiv. | equiv. | equiv. | baseline | equiv. | equiv. | equiv. | equiv. |
| Example 6 | equiv. | equiv. | equiv. | baseline | equiv. | equiv. | equiv. | equiv. |
| Example 7 | equiv. | equiv. | equiv. | baseline | equiv. | equiv. | equiv. | equiv. |
| Example 8 | equiv. | equiv. | equiv. | baseline | equiv. | equiv. | equiv. | equiv. |
| Example 9 | equiv. | equiv. | equiv. | baseline | equiv. | equiv. | equiv. | equiv. |
| Example 10 | equiv. | equiv. | equiv. | baseline | equiv. | equiv. | equiv. | equiv. |
| Example 11 | equiv. | equiv. | equiv. | baseline | equiv. | equiv. | equiv. | equiv. |
| Example 12 | equiv. | equiv. | equiv. | baseline | equiv. | equiv. | equiv. | equiv. |
| Example 13 | equiv. | equiv. | equiv. | baseline | equiv. | equiv. | equiv. | equiv. |
| Example 14 | equiv. | equiv. | equiv. | baseline | equiv. | equiv. | equiv. | equiv. |
| Example 15 | equiv. | equiv. | equiv. | baseline | equiv. | equiv. | equiv. | equiv. |
| Example 16 | equiv. | equiv. | equiv. | baseline | equiv. | equiv. | equiv. | equiv. |
| Example 17 | equiv. | equiv. | equiv. | baseline | equiv. | equiv. | equiv. | equiv. |
| Example 18 | equiv. | equiv. | equiv. | baseline | equiv. | equiv. | equiv. | equiv. |
| Example 19 | equiv. | equiv. | equiv. | baseline | equiv. | equiv. | equiv. | equiv. |
| Example 20 | equiv. | equiv. | equiv. | baseline | equiv. | equiv. | equiv. | equiv. |
| Comparative | unfav. | unfav. | unfav. | baseline | unfav. | unfav. | unfav. | unfav. |
| Example 1 | | | | | | | | |
| Comparative | unfav. | unfav. | unfav. | baseline | unfav. | unfav. | unfav. | unfav. |
| Example 2 | | | | | | | | |
| Comparative | unfav. | unfav. | unfav. | baseline | unfav. | unfav. | unfav. | unfav. |
| Example 3 | | | | | | | | |
| Comparative | unfav. | unfav. | unfav. | baseline | unfav. | unfav. | unfav. | unfav. |
| Example 4 | | | | | | | | |
| Comparative | unfav. | unfav. | unfav. | baseline | unfav. | unfav. | unfav. | unfav. |
| Example 5 | | | | | | | | |
| Comparative | unfav. | unfav. | unfav. | baseline | unfav. | unfav. | unfav. | unfav. |
| Example 6 | | | | | | | | |
| Comparative | unfav. | unfav. | unfav. | baseline | unfav. | unfav. | unfav. | unfav. |
| Example 7 | | | | | | | | |
| Comparative | unfav. | unfav. | unfav. | baseline | unfav. | unfav. | unfav. | unfav. |
| Example 8 | | | | | | | | |
| Comparative | unfav. | unfav. | unfav. | baseline | unfav. | unfav. | unfav. | unfav. |
| Example 9 | | | | | | | | |

As is clear from the results shown in Tables 4 and 5, any of the LWR performances, the resolutions and the sensitivities of the radiation-sensitive composition of Examples did not exhibit time-dependent alteration, whereas deteriorations of the LWR performance and the resolution as well as changes in the sensitivity were found on the radiation-sensitive compositions of Comparative Examples.

### Preparation of Radiation-Sensitive Composition (II)

### Example 21

A radiation-sensitive composition (R2-1) was prepared by blending 5 parts by mass of (A-1) as the particles (A), 10 parts by mass of (B-1) as the aggregation inhibiting agent (B), 3,104 parts by mass of (C-1) and 776 parts by mass of (C-2) as the organic solvent (C), 10 parts by mass of (D-1) as the acid generating agent (D), 2.3 parts by mass of (E-1) as the acid diffusion control agent (E) and 100 parts by mass of (F-1) as the polymer (F), and then filtering through a membrane filter having a pore size of 0.2 μm.

### Examples 22 to 40 and Comparative Examples 10 to 21

Radiation-sensitive resin compositions (R2-2) to (R2-20) and (CR2-1) to (CR2-12) were prepared by a similar operation to that of Example 21 except that the type and the content of each component used were as shown in Table 6 below.

TABLE 6

| | | | | (B) | | | | | | (E) Acid | | | |
|---|---|---|---|---|---|---|---|---|---|---|---|---|---|
| | | | | Aggregation | | | | (D) Acid | | diffusion | | | |
| | | (A) | | inhibiting | | | | generating | | control | | | |
| | | Particles | | agent | | (C) | | agent | | agent | | (F) Polymer | |
| | | | content | | content | Organic solvent | | | content | | content | | content |
| | Radiation- | | (parts | | (parts | | content | | (parts | | (parts | | (parts |
| | sensitive | | by | | by | | (parts by | | by | | by | | by |
| | composition | type | mass) | type | mass) | type | mass) | type | mass) | type | mass) | type | mass) |
| Example 21 | R2-1 | A-1 | 5 | B-1 | 10 | C-1/C-2 | 3,104/776 | D-1 | 10 | E-1 | 2.3 | F-1 | 100 |
| Example 22 | R2-2 | A-2 | 5 | B-1 | 10 | C-1/C-2 | 3,104/776 | D-1 | 10 | E-1 | 2.3 | F-1 | 100 |
| Example 23 | R2-3 | A-3 | 5 | B-1 | 10 | C-1/C-2 | 3,104/776 | D-1 | 10 | E-1 | 2.3 | F-1 | 100 |
| Example 24 | R2-4 | A-4 | 5 | B-1 | 10 | C-1/C-2 | 3,104/776 | D-1 | 10 | E-1 | 2.3 | F-1 | 100 |
| Example 25 | R2-5 | A-5 | 5 | B-1 | 10 | C-1/C-2 | 3,104/776 | D-1 | 10 | E-1 | 2.3 | F-1 | 100 |
| Example 26 | R2-6 | A-6 | 5 | B-1 | 10 | C-1/C-2 | 3,104/776 | D-1 | 10 | E-1 | 2.3 | F-1 | 100 |
| Example 27 | R2-7 | A-7 | 5 | B-1 | 10 | C-1/C-2 | 3,104/776 | D-1 | 10 | E-1 | 2.3 | F-1 | 100 |
| Example 28 | R2-8 | A-1 | 5 | B-1 | 50 | C-1/C-2 | 3,104/776 | D-1 | 10 | E-1 | 2.3 | F-2 | 100 |
| Example 29 | R2-9 | A-1 | 5 | B-1 | 1 | C-1/C-2 | 3,104/776 | D-1 | 10 | E-1 | 2.3 | F-3 | 100 |
| Example 30 | R2-10 | A-1 | 5 | B-1 | 0.1 | C-1/C-2 | 3,104/776 | D-1 | 10 | E-1 | 2.3 | F-4 | 100 |
| Example 31 | R2-11 | A-1 | 5 | B-1 | 0.01 | C-1/C-2 | 3,104/776 | D-1 | 10 | E-1 | 2.3 | F-1 | 100 |
| Example 32 | R2-12 | A-1 | 5 | B-2 | 10 | C-1/C-2 | 3,104/776 | D-1 | 10 | E-1 | 2.3 | F-1 | 100 |
| Example 33 | R2-13 | A-1 | 5 | B-3 | 10 | C-1/C-2 | 3,104/776 | D-1 | 10 | E-1 | 2.3 | F-1 | 100 |
| Example 34 | R2-14 | A-1 | 5 | B-4 | 10 | C-1/C-2 | 3,104/776 | D-1 | 10 | E-1 | 2.3 | F-1 | 100 |
| Example 35 | R2-15 | A-1 | 5 | B-5 | 10 | C-1/C-2 | 3,104/776 | D-1 | 10 | E-1 | 2.3 | F-1 | 100 |
| Example 36 | R2-16 | A-1 | 5 | B-6 | 10 | C-1/C-2 | 3,104/776 | D-1 | 10 | E-1 | 2.3 | F-1 | 100 |
| Example 37 | R2-17 | A-1 | 5 | B-7 | 10 | C-1/C-2 | 3,104/776 | D-1 | 10 | E-1 | 2.3 | F-1 | 100 |
| Example 38 | R2-18 | A-1 | 5 | B-8 | 10 | C-1/C-2 | 3,104/776 | D-1 | 10 | E-1 | 2.3 | F-1 | 100 |
| Example 39 | R2-19 | A-1 | 10 | B-1 | 10 | C-1/C-2 | 3,104/776 | D-1 | 10 | E-1 | 2.3 | F-1 | 100 |
| Example 40 | R2-20 | A-1 | 5 | B-1 | 10 | C-1/C-2 | 3,104/776 | D-1 | 10 | E-2 | 2.3 | F-1 | 100 |
| Comparative | CR2-1 | A-1 | 5 | — | — | C-1/C-2 | 3,104/776 | D-1 | 10 | E-1 | 2.3 | F-1 | 100 |
| Example 10 | | | | | | | | | | | | | |
| Comparative | CR2-2 | A-2 | 5 | — | — | C-1/C-2 | 3,104/776 | D-1 | 10 | E-1 | 2.3 | F-1 | 100 |
| Example 11 | | | | | | | | | | | | | |
| Comparative | CR2-3 | A-3 | 5 | — | — | C-1/C-2 | 3,104/776 | D-1 | 10 | E-1 | 2.3 | F-1 | 100 |
| Example 12 | | | | | | | | | | | | | |
| Comparative | CR2-4 | A-4 | 5 | — | — | C-1/C-2 | 3,104/776 | D-1 | 10 | E-1 | 2.3 | F-1 | 100 |
| Example 13 | | | | | | | | | | | | | |
| Comparative | CR2-5 | A-5 | 5 | — | — | C-1/C-2 | 3,104/776 | D-1 | 10 | E-1 | 2.3 | F-1 | 100 |
| Example 14 | | | | | | | | | | | | | |
| Comparative | CR2-6 | A-6 | 5 | — | — | C-1/C-2 | 3,104/776 | D-1 | 10 | E-1 | 2.3 | F-1 | 100 |
| Example 15 | | | | | | | | | | | | | |
| Comparative | CR2-7 | A-7 | 5 | — | — | C-1/C-2 | 3,104/776 | D-1 | 10 | E-1 | 2.3 | F-1 | 100 |
| Example 16 | | | | | | | | | | | | | |
| Comparative | CR2-8 | A-1 | 5 | — | — | C-1/C-2 | 3,104/776 | D-1 | 10 | E-1 | 2.3 | F-2 | 100 |
| Example 17 | | | | | | | | | | | | | |
| Comparative | CR2-9 | A-1 | 5 | — | — | C-1/C-2 | 3,104/776 | D-1 | 10 | E-1 | 2.3 | F-3 | 100 |
| Example 18 | | | | | | | | | | | | | |
| Comparative | CR2-10 | A-1 | 5 | — | — | C-1/C-2 | 3,104/776 | D-1 | 10 | E-1 | 2.3 | F-4 | 100 |
| Example 19 | | | | | | | | | | | | | |
| Comparative | CR2-11 | A-1 | 10 | — | — | C-1/C-2 | 3,104/776 | D-1 | 10 | E-1 | 2.3 | F-1 | 100 |
| Example 20 | | | | | | | | | | | | | |
| Comparative | CR2-12 | A-1 | 5 | — | — | C-1/C-2 | 3,104/776 | D-1 | 10 | E-2 | 2.3 | F-1 | 100 |
| Example 21 | | | | | | | | | | | | | |

Resist Pattern Formation (3): Development with Alkali

The radiation-sensitive composition prepared as described above was applied on the surface of an 8-inch silicon wafer by using a spin coater (“CLEAN TRACK ACTS”, available from Tokyo Electron Limited), and PB was carried out at 90° C. for 60 sec. Thereafter, a resist film having an average thickness of 35 nm was formed through cooling at 23° C. for 30 sec. Next, the resist film was irradiated with an electron beam by using a simplified electron beam writer (“HL800D” available from Hitachi, Ltd.; output: 50 KeV, electric current density: 5.0 A/cm²). Then, a development was carried out at 23° C. for 30 sec with a 2.38% by mass aqueous TMAH solution as an alkaline developer solution, followed by washing with water and drying to form a positive-tone resist pattern.

### Evaluations

On respective radiation-sensitive compositions of immediately after the preparation (T=0), and 2 weeks later (T=2 w), 4 weeks later (T=4 w), 8 weeks later (T=8 w) and 12 weeks later (T=12 w) during the storage at 5° C., the LWR performance, the resolution and the sensitivity were determined according to methods similar to those described above. The results of the evaluations are shown in Table 7. For the measurement of the pattern line-width, a scanning electron microscope (“S-9380”, available from Hitachi High-Technologies Corporation) was used.

TABLE 7

| | Radiation- | Development with alkali | | | | | | |
|---|---|---|---|---|---|---|---|---|
| | sensitive | LWR performance | | | | | Resolution | |
| | composition | T = 0 | T = 2 w | T = 4 w | T = 8 w | T = 12 w | T = 0 | T = 2 w |
| Example 21 | R2-1 | baseline | equiv. | equiv. | equiv. | equiv. | baseline | equiv. |
| Example 22 | R2-2 | baseline | equiv. | equiv. | equiv. | equiv. | baseline | equiv. |
| Example 23 | R2-3 | baseline | equiv. | equiv. | equiv. | equiv. | baseline | equiv. |
| Example 24 | R2-4 | baseline | equiv. | equiv. | equiv. | equiv. | baseline | equiv. |
| Example 25 | R2-5 | baseline | equiv. | equiv. | equiv. | equiv. | baseline | equiv. |
| Example 26 | R2-6 | baseline | equiv. | equiv. | equiv. | equiv. | baseline | equiv. |
| Example 27 | R2-7 | baseline | equiv. | equiv. | equiv. | equiv. | baseline | equiv. |
| Example 28 | R2-8 | baseline | equiv. | equiv. | equiv. | equiv. | baseline | equiv. |
| Example 29 | R2-9 | baseline | equiv. | equiv. | equiv. | equiv. | baseline | equiv. |
| Example 30 | R2-10 | baseline | equiv. | equiv. | equiv. | equiv. | baseline | equiv. |
| Example 31 | R2-11 | baseline | equiv. | equiv. | equiv. | equiv. | baseline | equiv. |
| Example 32 | R2-12 | baseline | equiv. | equiv. | equiv. | equiv. | baseline | equiv. |
| Example 33 | R2-13 | baseline | equiv. | equiv. | equiv. | equiv. | baseline | equiv. |
| Example 34 | R2-14 | baseline | equiv. | equiv. | equiv. | equiv. | baseline | equiv. |
| Example 35 | R2-15 | baseline | equiv. | equiv. | equiv. | equiv. | baseline | equiv. |
| Example 36 | R2-16 | baseline | equiv. | equiv. | equiv. | equiv. | baseline | equiv. |
| Example 37 | R2-17 | baseline | equiv. | equiv. | equiv. | equiv. | baseline | equiv. |
| Example 38 | R2-18 | baseline | equiv. | equiv. | equiv. | equiv. | baseline | equiv. |
| Example 39 | R2-19 | baseline | equiv. | equiv. | equiv. | equiv. | baseline | equiv. |
| Example 40 | R2-20 | baseline | equiv. | equiv. | equiv. | equiv. | baseline | equiv. |
| Comparative | CR2-1 | baseline | unfav. | unfav. | unfav. | unfav. | baseline | unfav. |
| Example 10 | | | | | | | | |
| Comparative | CR2-2 | baseline | unfav. | unfav. | unfav. | unfav. | baseline | unfav. |
| Example 11 | | | | | | | | |
| Comparative | CR2-3 | baseline | unfav. | unfav. | unfav. | unfav. | baseline | unfav. |
| Example 12 | | | | | | | | |
| Comparative | CR2-4 | baseline | unfav. | unfav. | unfav. | unfav. | baseline | unfav. |
| Example 13 | | | | | | | | |
| Comparative | CR2-5 | baseline | unfav. | unfav. | unfav. | unfav. | baseline | unfav. |
| Example 14 | | | | | | | | |
| Comparative | CR2-6 | baseline | unfav. | unfav. | unfav. | unfav. | baseline | unfav. |
| Example 15 | | | | | | | | |
| Comparative | CR2-7 | baseline | unfav. | unfav. | unfav. | unfav. | baseline | unfav. |
| Example 16 | | | | | | | | |
| Comparative | CR2-8 | baseline | unfav. | unfav. | unfav. | unfav. | baseline | unfav. |
| Example 17 | | | | | | | | |
| Comparative | CR2-9 | baseline | unfav. | unfav. | unfav. | unfav. | baseline | unfav. |
| Example 18 | | | | | | | | |
| Comparative | CR2-10 | baseline | unfav. | unfav. | unfav. | unfav. | baseline | unfav. |
| Example 19 | | | | | | | | |
| Comparative | CR2-11 | baseline | unfav. | unfav. | unfav. | unfav. | baseline | unfav. |
| Example 20 | | | | | | | | |
| Comparative | CR2-12 | baseline | unfav. | unfav. | unfav. | unfav. | baseline | unfav. |
| Example 21 | | | | | | | | |

| | Development with alkali | | | | | | | |
|---|---|---|---|---|---|---|---|---|
| | Resolution | | | Sensitivity | | | | |
| | T = 4 w | T = 8 w | T = 12 w | T = 0 | T = 2 w | T = 4 w | T = 8 w | T = 12 w |
| Example 21 | equiv. | equiv. | equiv. | baseline | equiv. | equiv. | equiv. | equiv. |
| Example 22 | equiv. | equiv. | equiv. | baseline | equiv. | equiv. | equiv. | equiv. |
| Example 23 | equiv. | equiv. | equiv. | baseline | equiv. | equiv. | equiv. | equiv. |
| Example 24 | equiv. | equiv. | equiv. | baseline | equiv. | equiv. | equiv. | equiv. |
| Example 25 | equiv. | equiv. | equiv. | baseline | equiv. | equiv. | equiv. | equiv. |
| Example 26 | equiv. | equiv. | equiv. | baseline | equiv. | equiv. | equiv. | equiv. |
| Example 27 | equiv. | equiv. | equiv. | baseline | equiv. | equiv. | equiv. | equiv. |
| Example 28 | equiv. | equiv. | equiv. | baseline | equiv. | equiv. | equiv. | equiv. |
| Example 29 | equiv. | equiv. | equiv. | baseline | equiv. | equiv. | equiv. | equiv. |
| Example 30 | equiv. | equiv. | equiv. | baseline | equiv. | equiv. | equiv. | equiv. |
| Example 31 | equiv. | equiv. | equiv. | baseline | equiv. | equiv. | equiv. | equiv. |
| Example 32 | equiv. | equiv. | equiv. | baseline | equiv. | equiv. | equiv. | equiv. |
| Example 33 | equiv. | equiv. | equiv. | baseline | equiv. | equiv. | equiv. | equiv. |
| Example 34 | equiv. | equiv. | equiv. | baseline | equiv. | equiv. | equiv. | equiv. |
| Example 35 | equiv. | equiv. | equiv. | baseline | equiv. | equiv. | equiv. | equiv. |
| Example 36 | equiv. | equiv. | equiv. | baseline | equiv. | equiv. | equiv. | equiv. |
| Example 37 | equiv. | equiv. | equiv. | baseline | equiv. | equiv. | equiv. | equiv. |
| Example 38 | equiv. | equiv. | equiv. | baseline | equiv. | equiv. | equiv. | equiv. |
| Example 39 | equiv. | equiv. | equiv. | baseline | equiv. | equiv. | equiv. | equiv. |
| Example 40 | equiv. | equiv. | equiv. | baseline | equiv. | equiv. | equiv. | equiv. |
| Comparative | unfav. | unfav. | unfav. | baseline | unfav. | unfav. | unfav. | unfav. |
| Example 10 | | | | | | | | |
| Comparative | unfav. | unfav. | unfav. | baseline | unfav. | unfav. | unfav. | unfav. |
| Example 11 | | | | | | | | |
| Comparative | unfav. | unfav. | unfav. | baseline | unfav. | unfav. | unfav. | unfav. |
| Example 12 | | | | | | | | |
| Comparative | unfav. | unfav. | unfav. | baseline | unfav. | unfav. | unfav. | unfav. |
| Example 13 | | | | | | | | |
| Comparative | unfav. | unfav. | unfav. | baseline | unfav. | unfav. | unfav. | unfav. |
| Example 14 | | | | | | | | |
| Comparative | unfav. | unfav. | unfav. | baseline | unfav. | unfav. | unfav. | unfav. |
| Example 15 | | | | | | | | |
| Comparative | unfav. | unfav. | unfav. | baseline | unfav. | unfav. | unfav. | unfav. |
| Example 16 | | | | | | | | |
| Comparative | unfav. | unfav. | unfav. | baseline | unfav. | unfav. | unfav. | unfav. |
| Example 17 | | | | | | | | |
| Comparative | unfav. | unfav. | unfav. | baseline | unfav. | unfav. | unfav. | unfav. |
| Example 18 | | | | | | | | |
| Comparative | unfav. | unfav. | unfav. | baseline | unfav. | unfav. | unfav. | unfav. |
| Example 19 | | | | | | | | |
| Comparative | unfav. | unfav. | unfav. | baseline | unfav. | unfav. | unfav. | unfav. |
| Example 20 | | | | | | | | |
| Comparative | unfav. | unfav. | unfav. | baseline | unfav. | unfav. | unfav. | unfav. |
| Example 21 | | | | | | | | |

As is clear from the results shown in Table 7, any of the LWR performances, the resolutions and the sensitivities of the radiation-sensitive composition of Examples did not exhibit time-dependent alteration, whereas deteriorations of the LWR performance and the resolution as well as changes in the sensitivity were found on the radiation-sensitive compositions of Comparative Examples.

The radiation-sensitive composition and the pattern-forming method of the embodiments of the present invention enable metal-containing particles that are conventionally inferior in storage stability to be stably stored, and enable deterioration of pattern formability to be prevented. In general, an electron beam exposure is known to exhibit a similar tendency to the case of an EUV exposure, and therefore, the radiation-sensitive resin compositions of Examples are assumed to be superior in the storage stability also in the case of the EUV exposure.

According to the radiation-sensitive composition and the pattern-forming method of the embodiments of the present invention, even when the radiation-sensitive composition is stored for a long period of time, formation of a pattern with high sensitivity, less LWR and high resolution is enabled. Therefore, these can be suitably used for formation of fine resist patterns in lithography processes of various types of electronic devices such as semiconductor devices and liquid crystal devices in which further progress of microfabrication is expected in the future.

Obviously, numerous modifications and variations of the present invention are possible in light of the above teachings. It is therefore to be understood that within the scope of the appended claims, the invention may be practiced otherwise than as specifically described herein.

1. A radiation-sensitive composition comprising:
particles comprising a metal oxide as a principal component;
an aggregation inhibiting agent for inhibiting aggregation of the particles; and
an organic solvent.

2. The radiation-sensitive composition according to claim 1, wherein the aggregation inhibiting agent is a compound having dehydration ability.

3. The radiation-sensitive composition according to claim 2, wherein the compound having dehydration ability is a carboxylic anhydride, an orthocarboxylic acid ester, a carboxylic acid halide or a combination thereof.

4. The radiation-sensitive composition according to claim 1, wherein the aggregation inhibiting agent is a compound that is capable of coordinating to a metal atom.

5. The radiation-sensitive composition according to claim 4, wherein the compound that is capable of coordinating to a metal atom is represented by formula (1):
R¹X)ₙ (1)
wherein, in the formula (1),
R¹ represents an organic group having a valency of n;
X represents —OH, —COOH, —NCO, —NHR^{a}, —COOR^{A} or —CO—C(R^{L})₂—CO—R^{A}, wherein
R^{a} represents a hydrogen atom or a monovalent organic group,
R^{A} represents a monovalent organic group, and
R^{L}s each independently represent a hydrogen atom or a monovalent organic group; and
n is an integer of 1 to 4, wherein in a case where n is 2 or greater, a plurality of Xs are identical or different.

6. The radiation-sensitive composition according to claim 1, wherein a content of the aggregation inhibiting agent with respect to 100 parts by mass of the particles is no less than 0.001 parts by mass.

7. The radiation-sensitive composition according to claim 1, wherein a metal atom constituting the metal oxide is at least one atom selected from group 3, group 4, group 5, group 6, group 7, group 8, group 9, group 10, group 11, group 12, group 13 and group 14.

8. The radiation-sensitive composition according to claim 7, wherein the metal atom constituting the metal oxide is a titanium atom, a zirconium atom, a hafnium atom, a tantalum atom, a tungsten atom, a tin atom or a combination thereof.

9. The radiation-sensitive composition according to claim 1, comprising the particles as a principal component in a total solid content.

10. The radiation-sensitive composition according to claim 1, further comprising a polymer comprising an acid-labile group.

11. The radiation-sensitive composition according to claim 9, further comprising a radiation-sensitive acid generator.

12. A pattern-forming method comprising:
applying the radiation-sensitive composition according to claim 1 directly or indirectly on one face side of a substrate;
exposing a film obtained after the applying; and
developing the film exposed.

13. The pattern-forming method according to claim 12, wherein a developer solution used in the developing is an alkaline aqueous solution.

14. The pattern-forming method according to claim 12, wherein a developer solution used in the developing is an organic solvent-containing liquid.

15. The pattern-forming method according to claim 12, wherein a radioactive ray used in the exposing is an extreme ultraviolet ray or an electron beam.

16. The radiation-sensitive composition according to claim 9, wherein a content of the particles with respect to the total solid content is no less than 50% by mass.

17. The radiation-sensitive composition according to claim 1, wherein a mean particle diameter of the particles is no greater than 20 nm.

18. The radiation-sensitive composition according to claim 7, wherein the atom selected from group 4 is a zirconium atom, a hafnium atom, or both thereof.
